(19) United States
(12) Patent Application Publication
(10) Pub. No.: US 2024/0324341 A1
(43) Pub. Date: Sep. 26, 2024

(54) DISPLAY APPARATUS

(71) Applicant: Samsung Display Co., Ltd., Yongin-si (KR)

(72) Inventors: Gwuihyun Park, Yongin-si (KR); Hokyung Jang, Yongin-si (KR); Koichi Sugitani, Yongin-si (KR)

(73) Assignee: Samsung Display Co., Ltd., Yongin-si (KR)

(21) Appl. No.: 18/434,108

(22) Filed: Feb. 6, 2024

(30) Foreign Application Priority Data
Mar. 24, 2023 (KR) 10-2023-0039240
Mar. 30, 2023 (KR) 10-2023-0042249

(51) Int. Cl. H10K 59/131; H10K 59/124

(52) U.S. Cl. CPC H10K 59/131; H10K 59/124

(57) ABSTRACT

A display apparatus includes a display area and a peripheral area, a light-emitting diode including a sub-pixel electrode, a first data line in the display area and extending in a first direction, an input line in the peripheral area, and a connection wire in the display area and transmitting a data signal input to the first data line. The connection wire includes a first connection line extending in the first direction and a second connection line extending in a second direction, the first connection line overlaps the sub-pixel electrode with an insulating layer interposed between the sub-pixel electrode and the first connection line, the insulating layer includes a first insulating layer and a second insulating layer disposed on the first insulating layer, dielectric constants of the first and second insulating layers are different, and one of the first insulating layer and the second insulating layer includes BCB.

### CROSS REFERENCE TO RELATED APPLICATION(S)

This application claims priority to and benefits of Korean Patent Application No. 10-2023-0039240 under 35 U.S.C. § 119, filed on Mar. 24, 2023, in the Korean Intellectual Property Office (KIPO), and Korean Patent Application No. 10-2023-0042249 under 35 U.S.C. § 119, filed on Mar. 30, 2023, in the Korean Intellectual Property Office (KIPO), the entire contents of which are incorporated herein by reference.

### BACKGROUND

### 1. Technical Field

Embodiments relate to a display apparatus that displays a high-quality image.

### 2. Description of the Related Art

Generally, in a display apparatus such as an organic light-emitting display apparatus or the like, thin film transistors are arranged in each sub-pixel and control luminance and the like of each sub-pixel. The thin film transistors control the luminance and the like of a corresponding sub-pixel according to transmitted data signals and the like.

A data signal is transmitted to each sub-pixel through a data line from a driving part located in a peripheral area located adjacent to a display area.

### SUMMARY

The disclosure provides a display apparatus that displays a high-quality image while reducing an area of a dead space in which no light-emitting element is arranged. However, such an objective is an example, and the scope of the disclosure is not limited thereto.

Additional aspects will be set forth in part in the description which follows and, in part, will be apparent from the description, or may be learned by practice of the presented embodiments of the disclosure.

According to an embodiment, a display apparatus may include a display area and a peripheral area located adjacent to the display area, a sub-pixel circuit on a substrate, a light-emitting diode electrically connected to the sub-pixel circuit and including a sub-pixel electrode, a first data line located in the display area and extending in a first direction, an input line located in the peripheral area and extending toward the display area from the peripheral area, and a connection wire located in the display area and transmitting a data signal input through the input line to the first data line. The connection wire may include a first connection line extending in the first direction and a second connection line extending in a second direction intersecting the first direction, the first connection line may overlap the sub-pixel electrode in a plan view with an insulating layer interposed between the sub-pixel electrode and the first connection line, the insulating layer may include a first insulating layer and a second insulating layer disposed on the first insulating layer, a dielectric constant of the first insulating layer and a dielectric constant of the second insulating layer may have different from each other, and one of the first insulating layer and the second insulating layer may include benzocyclobutene (BCB).

In an embodiment, the dielectric constant of the first insulating layer may be lower than the dielectric constant of the second insulating layer, and the first insulating layer may include BCB.

In an embodiment, the dielectric constant of the second insulating layer may be lower than the dielectric constant of the first insulating layer, and the second insulating layer may include BCB.

In an embodiment, a roughness of an upper surface of the second insulating layer may be greater than a roughness of an upper surface of the first insulating layer.

In an embodiment, the second insulating layer may further include a photosensitive material.

In an embodiment, the first connection line and the second connection line may be integrally formed.

In an embodiment, the display apparatus may further include a second data line spaced apart from the first data line, intersecting the second connection line, and extending in the first direction. The second connection line may pass above the second data line and not be connected with the second data line.

In an embodiment, the first connection line and the second connection line may be disposed on different layers, and the first connection line and the first data line may be disposed on a same layer.

In an embodiment, the display apparatus may further include a second data line spaced apart from the first data line, intersecting the second connection line, and extending in the first direction. The second connection line may pass under the second data line and not be connected with the second data line.

In an embodiment, the connection wire may further include a third connection line located in the display area and extending in the first direction, and the third connection line may be connected to the first data line in the peripheral area located adjacent to the display area.

According to an embodiment, a display apparatus may include a display area and a peripheral area located adjacent to the display area, a sub-pixel circuit on a substrate, a light-emitting diode electrically connected to the sub-pixel circuit and including a sub-pixel electrode, a first data line and a second data line located in the display area, extending in a first direction, and spaced apart from each other, an input line located in the peripheral area and extending toward the display area from the peripheral area, and a connection wire having an end electrically connected to the input line and another end electrically connected to the first data line, and passing through a portion of the display area located adjacent to the peripheral area. The connection wire may include a first connection line extending in the first direction and a second connection line extending in a second direction intersecting the first direction and intersecting the second data line, the first connection line may overlap the sub-pixel electrode in a plan view with an insulating layer interposed between the sub-pixel electrode and the first connection line, the insulating layer may include a first insulating layer and a second insulating layer disposed on the first insulating layer, a dielectric constant of the first insulating layer and a dielectric constant of the second insulating layer may be different from each other, and one of the first insulating layer and the second insulating layer may include benzocyclobutene (BCB).

In an embodiment, the dielectric constant of the first insulating layer may be lower than the dielectric constant of the second insulating layer, and the first insulating layer may include BCB.

In an embodiment, the dielectric constant of the second insulating layer may be lower than the dielectric constant of the first insulating layer, and the second insulating layer may include BCB.

In an embodiment, a roughness of an upper surface of the second insulating layer may be greater than a roughness of an upper surface of the first insulating layer.

In an embodiment, the second insulating layer may further include a photosensitive material.

In an embodiment, the first connection line and the second connection line may be integrally formed.

In an embodiment, the second connection line may be insulated from the second data line and pass above the second data line.

In an embodiment, the first connection line and the first data line may be disposed on a same layer.

In an embodiment, the second connection line may pass under the second data line, and the second connection line and the first connection line may be disposed on different layers.

In an embodiment, the connection wire may further include a third connection line located in the display area and extending in the first direction, and the third connection line may be connected to the first data line in the peripheral area located adjacent to the display area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a portion of a display apparatus according to an embodiment;

FIGS. 2A and 2B are schematic plan views of region A of the display apparatus of FIG. 1;

FIG. 3A is a schematic enlarged plan view of region A of the display apparatus of FIG. 2A;

FIG. 3B is a schematic enlarged plan view of region A of the display apparatus of FIG. 2B;

FIG. 4A is a schematic diagram of an equivalent circuit of a sub-pixel of a display apparatus according to an embodiment;

FIG. 4B is a schematic diagram of an equivalent circuit of a sub-pixel of a display apparatus according to an embodiment;

FIG. 5 is a schematic cross-sectional view of a portion of a display area in which a connection wire is arranged, of a display apparatus according to an embodiment;

FIG. 6 is a schematic cross-sectional view of a portion of a display area in which a connection wire is arranged, of a display apparatus according to an embodiment;

FIG. 7 is a schematic cross-sectional view of a portion of a display area in which a connection wire is arranged, of a display apparatus according to an embodiment;

FIG. 8 is a schematic cross-sectional view of a portion of a display area in which a connection wire is arranged, of a display apparatus according to an embodiment;

FIG. 9 is a schematic cross-sectional view of a portion of a display area in which a connection wire is arranged, of a display apparatus according to an embodiment;

FIG. 10 is a schematic cross-sectional view of a portion of a display area in which a connection wire is arranged, of a display apparatus according to an embodiment;

FIGS. 11A to 11D are schematic cross-sectional views illustrating a method of manufacturing the display apparatus of FIG. 5; and

FIGS. 12A to 12C are schematic cross-sectional views illustrating a method of manufacturing the display apparatus of FIG. 6.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. Throughout the disclosure, the expression “at least one of a, b, and c” indicates only a, only b, only c, both a and b, both a and c, both b and c, all of a, b, and c, or variations thereof.

Various modifications may be applied to the embodiments, and particular embodiments will be illustrated in the drawings and described in the detailed description section. The effect and features of the embodiments, and a method to achieve the same, will be clearer referring to the detailed descriptions below with the drawings. However, the embodiments may be implemented in various forms, not by being limited to the embodiments presented below.

The terminology used herein is for the purpose of describing particular embodiments and is not intended to be limiting. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

In the following embodiment, it will be understood that although the terms “first,” “second,” etc. may be used herein to describe various elements, these elements should not be limited by these terms. These elements are only used to distinguish one element from another. Thus, a first element discussed below could be termed a second element without departing from the teachings of the disclosure.

In the following embodiment, as used herein, the singular forms “a,” “an,” and “the” are intended to include the plural forms as well, unless the context clearly indicates otherwise.

In the following embodiment, it will be further understood that the terms “comprises,” “includes,” “has,” “comprising,” “including,” and/or “having,” when used in this specification, specify the presence of stated components, elements, features, integers, steps, operations, and/or groups thereof, but do not preclude the presence or addition of one or more other components, elements, features, integers, steps, operations, and/or groups thereof.

In the following embodiment, it will be understood that when an element, such as a layer, a film, a region, or a plate, is referred to as being “on” another element, the element can be directly on the other element or intervening elements may be present thereon. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the x direction, the y direction, and the z direction are not limited to three axes of a rectangular coordinate system, such as the x, y, and z directions, and may be interpreted in a broader sense. For example, the x direction, the y direction, and the z direction may be perpendicular to one another, or may represent different directions that are not perpendicular to one another.

When a component is described herein to “connect” another component to the other component or to be “connected to” other components, the components may be connected to each other as separate elements, or the components may be integral with each other.

Throughout the specification, when an element is referred to as being “connected” to another element, the element may be “directly connected” to another element, or “electrically connected” to another element with one or more intervening elements interposed therebetween.

It will be understood that when an element such as a layer, film, region, or substrate is referred to as being “on” or “above” another element, it can be directly on the other element or intervening element(s) may also be present. In contrast, when an element is referred to as being “directly on” another element, no intervening elements are present.

Spatially relative terms, such as “below,” “under,” “lower,” “above,” “upper,” “higher,” “side,” and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

As used herein, the term “and/or” includes any and all combinations of one or more of the associated listed items. In the specification, the expression such as “A and/or B” may include A, B, or A and B. Furthermore, in the specification, the expression such as “at least one of A and B” may include A, B, or A and B. The terms “and” and “or” may be used in the conjunctive or disjunctive sense and may be understood to be equivalent to “and/or.”

In the following embodiment, the meaning that the wiring “extends in the first direction or the second direction” includes not only extending in a linear shape, but also extending in a zigzag or a curve along the first direction or the second direction.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

In the following embodiment, when referred to as “in a plan view,” this means when an object part is viewed from above, and when it is referred to as “in a cross-sectional view,” it means when the cross-section where the object part is cut vertically is viewed from the side. In the following embodiments, when referred to as “overlapping,” it includes overlapping “in a plan view” and “in a cross-sectional view.”

The display surface may be parallel to a surface defined by an x direction and a y direction. A normal direction of the display surface, i.e., a thickness direction of the display apparatus, may indicate a z direction. In this specification, an expression of “when viewed from the top or in a plan view” may represent a case when viewed in the z direction. Hereinafter, a front surface (or a top surface) and a rear surface (or a bottom surface) of each of layers or units may be distinguished by the z direction. However, directions indicated by the x, y, and z directions may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described in detail with reference to the accompanying drawings, and in the description with reference to the drawings, the same or corresponding constituents are indicated by the same reference numerals and redundant descriptions thereof are omitted.

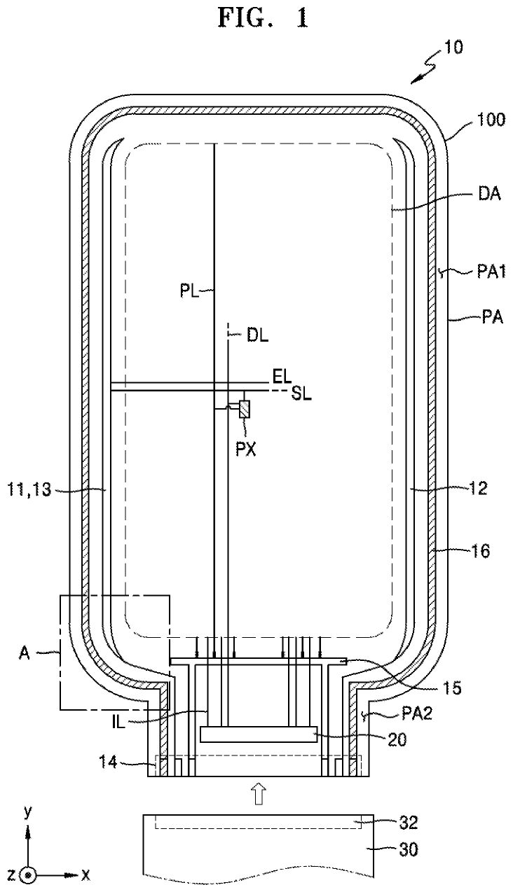

FIG. 1 is a schematic plan view of a portion of a display apparatus according to an embodiment.

Referring to FIG. 1, the display apparatus according to an embodiment may include a display panel 10. The display apparatus may be an apparatus including the display panel 10. For example, the display apparatus may be various products, such as a smartphone, a tablet computer, a laptop computer, a television, a billboard, or the like.

The display panel 10 may include a display area DA and a peripheral area PA arranged adjacent to the display area DA. The display area DA may be a portion for displaying an image, and multiple sub-pixels PX may be arranged in the display area DA. In a plan view, the display area DA may have a shape, such as a circular shape, an oval shape, a polygonal shape, a specific figure shape, and the like. FIG. 1 illustrates that the display area DA has an approximately rectangular shape with rounded corners, but the disclosure is not limited thereto.

The peripheral area PA may be arranged adjacent to the display area DA. For example, the peripheral PA may surround the display area DA. The peripheral area PA may include a first peripheral area PA1 at least partially surrounding a corner portion of the display area DA (e.g., in a −y direction and a −x direction), and a second peripheral area PA2 located at a side (e.g., an outer side) of the display area DA (e.g., in the −y direction). The y direction may intersect the x direction. The second peripheral area PA2 may be arranged adjacent to the first peripheral area PAL. For example, the second peripheral area PA2 may be located adjacent to the center of the display panel 10 relative to the first peripheral area PAL. A width (e.g., in the x direction) of the second peripheral area PA2 may be less than a width (e.g., in the x direction) of the display area DA. As described below, due to the structure described above, at least a portion of the second peripheral area PA2 may be readily bent.

The display panel 10 may include a substrate 100, and the substrate 100 may also include the display area DA and the peripheral area PA. In the following description, for convenience of explanation, the substrate 100 including the display area DA and the peripheral area PA will be described.

The display panel 10 may be bent around a bending axis in at least a portion of the second peripheral area PA2. As such, in case that the display panel 10 is bent, a portion of the second peripheral area PA2 may overlap the display area DA in a plan view. The second peripheral area PA2 may be a non-display area. In case that the display panel 10 is bent, and the display apparatus is viewed from a front surface (e.g., in a −z direction), a non-display area may not be perceived or even in case that a non-display area is perceived, an area that is perceived may be reduced. The z direction may intersect the x and y directions. However, the disclosure is not limited to a bendable display apparatus, and the disclosure may be applied to a non-bendable display apparatus.

A data driving part 20 may be arranged in the second peripheral area PA2 of the display panel 10. The data driving part 20 may include an integrated circuit (not shown) for driving the display panel 10. The integrated circuit may include a data driving integrated circuit (not shown) for generating a data signal, but the disclosure is not limited thereto.

The data driving part 20 may be mounted on the second peripheral area PA2 of the display panel 10. Because the data driving part 20 is mounted on a surface of the display area DA, in case that the display panel 10 is bent in the second peripheral area PA2, the data driving part 20 may be located on a rear surface of the display area DA.

A printed circuit board 30 and the like may be attached to a portion (e.g., an end portion) of the second peripheral area PA2 of the display panel 10. The printed circuit board 30 and the like may be electrically connected to the data driving part 20 and the like through a pad (not shown) on the substrate 100.

In the following description, although an organic light-emitting display apparatus is described as an embodiment of the display apparatus, the disclosure is not limited thereto. In another embodiment, the display apparatus may include an inorganic light-emitting display apparatus (or an inorganic electro-luminescent (EL) display apparatus), a quantum-dot light-emitting display apparatus, or the like. For example, an emission layer of a light-emitting element in the display apparatus may include an organic material, an inorganic material, the like, or a combination thereof. Furthermore, the display apparatus may include an emission layer and quantum dots located on a path of light emitted from the emission layer.

The display panel 10 may include the substrate 100. Various constituent elements of the display panel 10 may be located on the substrate 100. The substrate 100 may include glass, metal, a polymer resin, or the like. In case that the display panel 10 is bendable in the second peripheral area PA2, the substrate 100 may need to be flexible or bendable, and the substrate 100 may include, for example, a polymer resin such as polyethersulfone, polyacrylate, polyetherimide, polyethylene naphthalate, polyethylene terephthalate, polyphenylene sulfide, polyarylate, polyimide, polycarbonate, cellulose acetate propionate, the like, or a combination thereof. In an embodiment, the substrate 100 may have a multilayer structure including two layers including a polymer resin and a barrier layer including an inorganic material (a silicon oxide, a silicon nitride, a silicon oxynitride, the like, or a combination thereof) and arranged between the two layers.

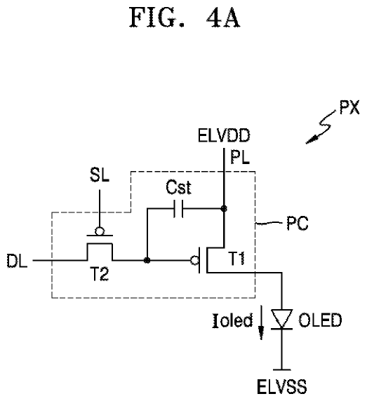

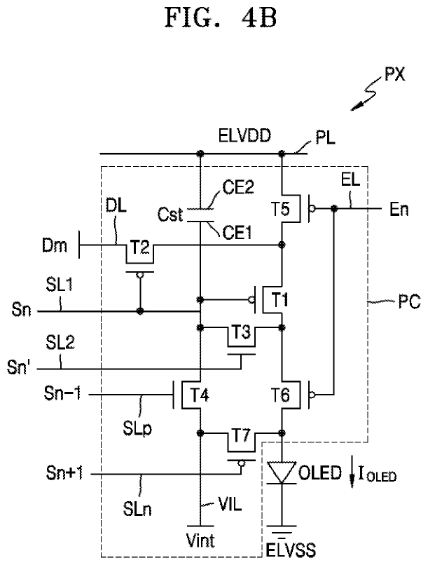

The sub-pixels PX may be located in the display area DA. Each of the sub-pixels PX may include a light-emitting element such as a light-emitting diode, organic light-emitting diode (OLED), or the like and a sub-pixel circuit (see, e.g., PC of FIG. 4A) electrically connected to the light-emitting element. The sub-pixel PX may emit, for example, red, green, blue, or white light. The sub-pixel PX may be electrically connected to circuits arranged in the peripheral area PA. A first scan driving part 11, a second scan driving part 12, an emission control driving part 13, a terminal 14, a driving voltage supply line 15, and a common voltage supply line 16 may be arranged in the peripheral area PA.

The first scan driving part 11 may provide a scan signal to the sub-pixel PX through a scan line SL. The second scan driving part 12 may be arranged parallel to the first scan driving part 11 with the display area DA disposed between the first scan driving part 11 and the second scan driving part 12. Some of the sub-pixels PX arranged in the display area DA may be electrically connected to the first scan driving part 11, and another of the sub-pixels PX arranged in the display area DA may be electrically connected to the second scan driving part 12. In another embodiment, the second scan driving part 12 may be omitted, and the sub-pixels PX arranged in the display area DA may all be electrically connected to the first scan driving part 11.

The emission control driving part 13 may be arranged at a side of the first scan driving part 11, and may provide an emission control signal to the sub-pixel PX through an emission control line EL. Although FIG. 1 illustrate that the emission control driving part 13 is arranged at only a side of the display area DA, the disclosure is not limited thereto, and the emission control driving part 13 may be arranged at both sides of the display area DA, similar to the first scan driving part 11 and the second scan driving part 12.

The terminal 14 may be arranged in the second peripheral area PA2 of the substrate 100. The terminal 14 may be exposed without being covered by an insulating layer and be electrically connected to the printed circuit board 30. A terminal 32 of the printed circuit board 30 may be electrically connected to the terminal 14 of the display panel 10.

The printed circuit board 30 may transmit a signal such as a control signal, a data signal, or the like or power of a controller (not shown) to the display panel 10. The control signal generated by the controller may be transmitted to each of driving parts 11, 12, and 13 through the printed circuit board 30. Furthermore, the controller may transmit a driving voltage (see, e.g., ELVDD of FIGS. 4A and 4B) to the driving voltage supply line 15, and a common voltage (see, e.g., ELVSS of FIGS. 4A and 4B) to the common voltage supply line 16. The driving voltage ELVDD may be transmitted to each sub-pixel PX through a driving voltage line PL electrically connected to the driving voltage supply line 15, and the common voltage ELVSS may be transmitted to a counter electrode (e.g., a common electrode) of the sub-pixel PX electrically connected to the common voltage supply line 16. The driving voltage supply line 15 may have a shape extending from the second peripheral area PA2 in a direction (e.g., the x direction). The common voltage supply line 16 having a loop shape with an open side may have a shape partially surrounding the display area DA.

The controller may generate a data signal, and the generated data signal may be transmitted to an input line IL through the data driving part 20, and to the sub-pixel PX through a data line DL electrically connected to the input line IL.

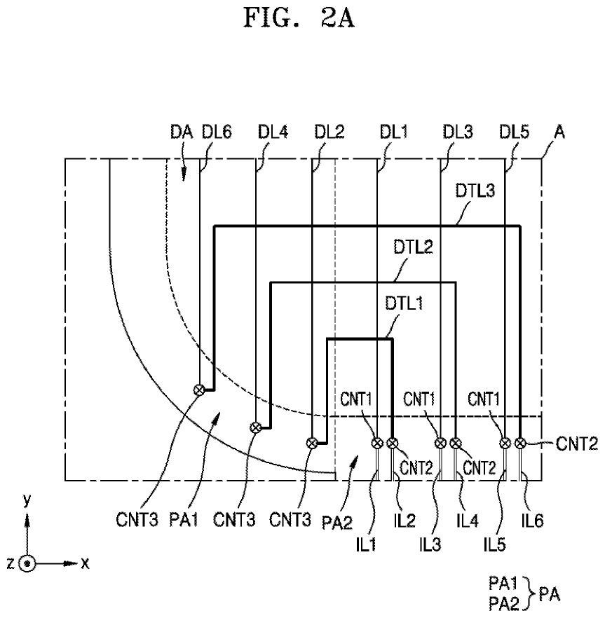

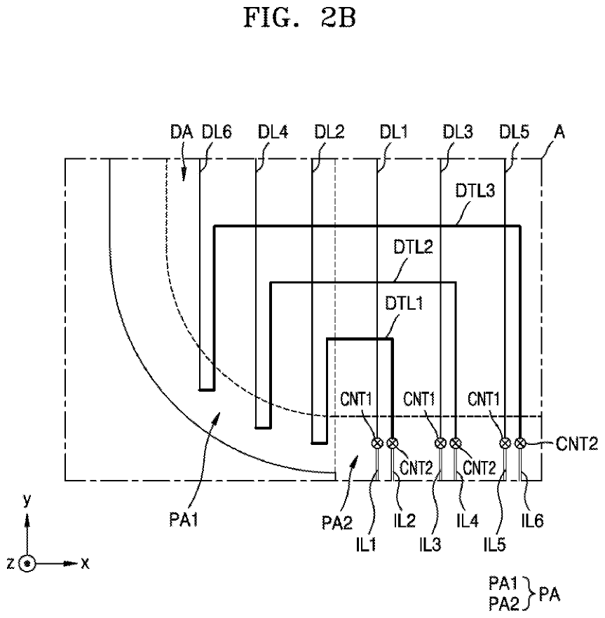

FIGS. 2A and 2B are schematic plan views of region A of the display apparatus of FIG. 1.

Various signals may be applied to the display area DA. For example, a data signal that adjusts brightness of each sub-pixel, and the like may be applied to the display area DA. A first data line DL1 to a sixth data line DL6 may be arranged in the display area DA in the first direction (e.g., the x direction) generally parallel to each other, and may extend in the second direction (e.g., the y direction) intersecting the first direction (e.g., the x direction). In an embodiment, the first data line DL1 to sixth data line DL6 may have a shape extending from the peripheral area PA to the display area DA. In addition to the first data line DL6 to the sixth data line DL6, various wires, such as a power line (not shown), a scan line (not shown), or the like may also be located in and out of (e.g., adjacent to) the display area DA.

A first input line IL1 to a sixth input line IL6 may be located in the peripheral area PA, for example, the second peripheral area PA2. The first input line IL1 to the sixth input line IL6 may be electrically connected to the data driving part 20 and receive a data signal. The first data line DL1 to the sixth data line DL6 may be electrically connected to the first input line IL1 to the sixth input line IL6, respectively, and transmit data signals to the sub-pixels PX in the display area DA.

FIGS. 2A and 2B illustrate, for convenience of explanation, six input lines IL1 to IL6 and six data lines DL1 to DL6. However, the disclosure is not limited thereto, and the number of each of the input lines (see, e.g., IL of FIG. 1) and the data lines (see, e.g., DL of FIG. 1) may be seven or more.

The first input line IL1 to the sixth input line IL6 may be sequentially arranged from an edge of the second peripheral area PA2 to the center of the second peripheral area PA2 (e.g., in the +x direction). In an embodiment, the first input line IL1 to the sixth input line IL6 may extend toward the display area DA from the second peripheral area PA2.

In an embodiment, the first input line IL1, the third input line IL3, and the fifth input line IL5, which are located at odd-numbered positions, may be electrically connected to the first data line DL1, the third data line DL3, and the fifth data line DL5, which are continuously arranged to neighbor each other. The first data line DL1, the third data line DL3, and the fifth data line DL5 may receive (e.g., directly receive) data signals from the first input line IL1, the third input line IL3, and the fifth input line IL5, respectively.

In an embodiment, the first input line IL1, the third input line IL3, and the fifth input line IL5 may be electrically connected to corresponding ones of the first data line DL1, the third data line DL3, and the fifth data line DL5, respectively, through a first contact hole CNT1. The first data line DL1, the third data line DL3, and the fifth data line DL5 may be disposed on a layer different from a layer the first input line IL1, the third input line IL3, and the fifth input line IL5 are disposed. Although FIGS. 2A and 2B illustrate that the first contact hole CNT1 is located in the second peripheral area PA2, the disclosure is not necessarily limited thereto. In another embodiment, the first contact hole CNT1 may be located in the display area DA.

In an embodiment, the second input line IL2, the fourth input line IL4, and the sixth input line IL6, which are located at even-numbered positions, may be electrically connected to the second data line DL2, the fourth data line DL4, and the sixth data line DL6, which are continuously arranged to neighbor each other, through a first connection wire DTL1, a second connection wire DTL2, and a third connection wire DTL3. For example, the second data line DL2, the fourth data line DL4, and the sixth data line DL6 may receive data signals from the second input line IL2, the fourth input line IL4, and the sixth input line IL6, through the first connection wire DTL1, the second connection wire DTL2, and the third connection wire DTL3.

The first connection wire DTL1 to the third connection wire DTL3 may pass a portion of the display area DA adjacent to the peripheral area PA, for example, may pass through the display area DA. The second input line IL2 may be electrically connected to the second data line DL2 through the first connection wire DTL1, the fourth input line IL4 may be electrically connected to the fourth data line DL4 through the second connection wire DTL2, and the sixth input line IL6 may be electrically connected to the sixth data line DL6 through the third connection wire DTL3.

Ends of the first connection wire DTL1, the second connection wire DTL2, and the third connection wire DTL3 may be electrically connected to the second input line IL2, the fourth input line IL4, and the sixth input line IL6, respectively, through a second contact hole CNT2. The first connection wire DTL1, the second connection wire DTL2, and the third connection wire DTL3 may be disposed on a layer different from a layer the second input line IL2, the fourth input line IL4, and the sixth input line IL6 are disposed. Although FIGS. 2A and 2B illustrate that the second contact hole CNT2 is located in the second peripheral area PA2, the disclosure is not necessarily limited thereto. In another embodiment, the second contact hole CNT2 may be located in the display area DA.

Another ends of the first connection wire DTL1, the second connection wire DTL2, and the third connection wire DTL3 may be electrically connected to the second data line DL2, the fourth data line DL4, and the sixth data line DL6, respectively. Referring to FIG. 2A, the another ends of the first connection wire DTL1, the second connection wire DTL2, and the third connection wire DTL3 may be electrically connected to the second data line DL2, the fourth data line DL4, and the sixth data line DL6, respectively, through a third contact hole CNT3. The first connection wire DTL1, the second connection wire DTL2, the third connection wire DTL3 may be disposed on a layer different from a layer the second data line DL2, the fourth data line DL4, and the sixth data line DL6 are disposed. Although FIG. 2A illustrates that the third contact hole CNT3 is located in the first peripheral area PA1, the disclosure is not necessarily limited thereto. In another embodiment, the third contact hole CNT3 may be located in the display area DA. Furthermore, referring to FIG. 2B, the first connection wire DTL1, the second connection wire DTL2, and the third connection wire DTL3 may be integrally formed with corresponding ones of the second data line DL2, the fourth data line DL4, and the sixth data line DL6, respectively The first connection wire DTL1, the second connection wire DTL2, and the third connection wire DTL3 may be disposed on a layer different from a layer the second data line DL2, the fourth data line DL4, and the sixth data line DL6 are disposed.

By the structure described above, the second input line IL2 may transmit a data signal to the second data line DL2, the fourth input line IL4 may transmit a data signal to the fourth data line DL4, and the sixth input line IL6 may transmit a data signal to the sixth data line DL6.

In the display apparatus according to an embodiment, in an area (e.g., a partial area) of the display area DA, as the data line DL is not directly connected to the input line IL, and is electrically connected to the input line through a connection wire that passes through the display area DA, the area of the peripheral area PA may be reduced. For example, as data signals of the second input line IL2, the fourth input line IL4, and the sixth input line IL6 are input to the second data line DL2, the fourth data line DL4, and the sixth data line DL6, respectively, through the first connection wire DTL1, the second connection wire DTL2, and the third connection wire DTL3, a dead space of a display apparatus may be reduced.

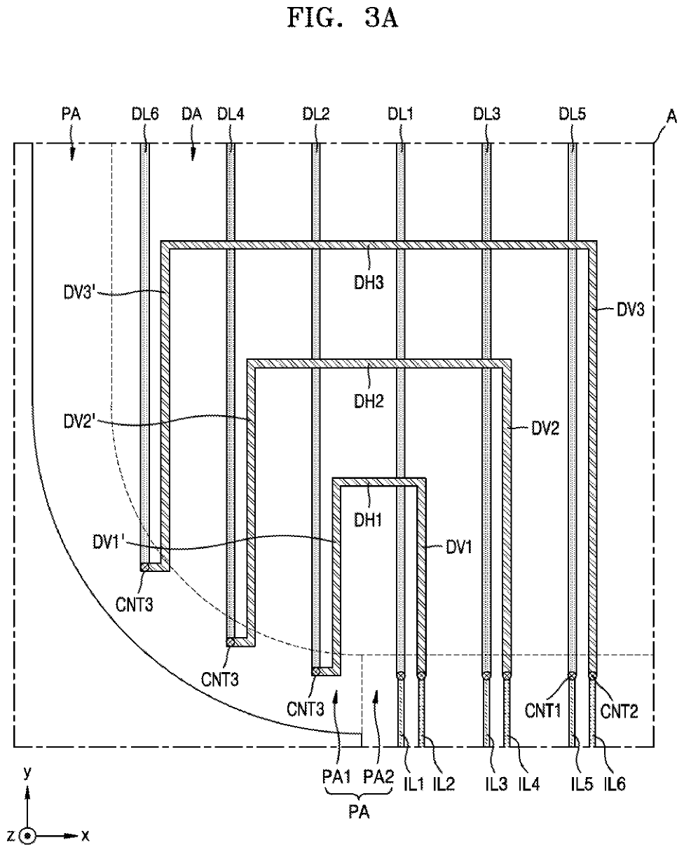

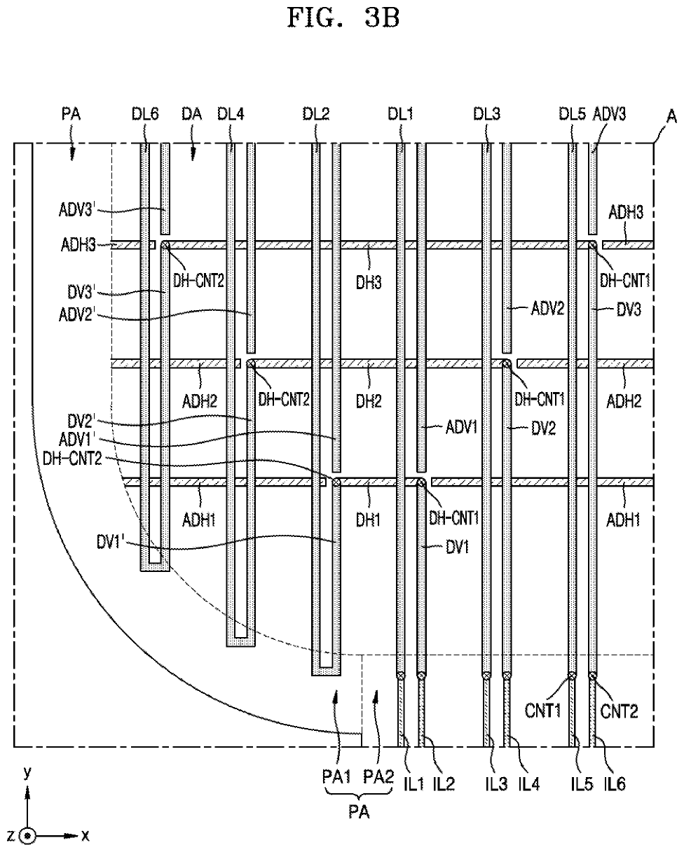

FIGS. 3A and 3B are schematic enlarged plan views of region A of the display apparatus of FIGS. 2A and 2B, respectively. FIGS. 3A and 3B respectively illustrate configurations of the first connection wire DTL1, the second connection wire DTL2, and the third connection wire DTL3 of FIGS. 2A and 2B.

Referring to FIGS. 3A and 3B, the first connection wire DTL1, the second connection wire DTL2, and the third connection wire DTL3 may each have a shape bent at least one time and be electrically connected to the second data line DL2, the fourth data line DL4, and the sixth data line DL6, respectively. The “bent shape” may mean not only a physical shape, but also a shape of a wire through electrical connection.

The first connection wire DTL1 may include a first vertical connection line (or a first connection line) DV1, a first horizontal connection line (or a second connection line) DH1, and a first additional vertical connection line DV1′. Similarly, the second connection wire DTL2 may include a second vertical connection line DV2, a second horizontal connection line DH2, and a second additional vertical connection line DV2′. The third connection wire DTL3 may include a third vertical connection line DV3, a third horizontal connection line DH3, and a third additional vertical connection line DV3′.

The first vertical connection line DV1 to the third vertical connection line DV3, and the first additional vertical connection line DV1′ to the third additional vertical connection line DV3′ may extend in the second direction (e.g., the y direction) approximately parallel to the first data line DL1 to the sixth data line DL6. The first horizontal connection line DH1 to the third horizontal connection line DH3 may have a shape extending in the first direction (e.g., the x direction) intersecting the second direction (e.g., the y direction) in which the first data line DL1 to the sixth data line DL6 extend.

In an embodiment, the second input line IL2, the fourth input line IL4, and the sixth input line IL6 may be electrically connected to corresponding ones of the first vertical connection line DV1, the second vertical connection line DV2, and the third vertical connection line DV3, respectively, through the second contact hole CNT2.

Ends of the first horizontal connection line DH1, the second horizontal connection line DH2, and the third horizontal connection line DH3 may be electrically connected to corresponding ones of the first vertical connection line DV1, the second vertical connection line DV2, and the third vertical connection line DV3, respectively, in the display area DA. Furthermore, another ends of the first horizontal connection line DH1, the second horizontal connection line DH2, and the third horizontal connection line DH3 may be electrically connected to corresponding ones of the first additional vertical connection line DV1′, the second additional vertical connection line DV2′, and the third additional vertical connection line DV3′, in the display area DA.

The first additional vertical connection line DV1′, the second additional vertical connection line DV2′, and the third additional vertical connection line DV3′ may be electrically connected to corresponding ones of the second data line DL2, the fourth data line DL4, and the sixth data line DL6, respectively. In an embodiment, the first additional vertical connection line DV1′, the second additional vertical connection line DV2′, and the third additional vertical connection line DV3′ may be electrically connected to corresponding ones of the second data line DL2, the fourth data line DL4, and the sixth data line DL6, in the peripheral area PA, in the first peripheral area PA1.

Referring to FIG. 3A, the first horizontal connection line DH1 to third horizontal connection line DH3 may be integrally formed with corresponding ones of the first vertical connection line DV1 to third vertical connection line DV3, respectively. Furthermore, the first horizontal connection line DH1 to third horizontal connection line DH3 may be integrally formed with corresponding ones of the first additional vertical connection line DV1′ to third additional vertical connection line DV3′, respectively.

The first additional vertical connection line DV1′, the second additional vertical connection line DV2′, and the third additional vertical connection line DV3′ may be electrically connected to corresponding ones of the second data line DL2, the fourth data line DL4, and the sixth data line DL6, through the third contact hole CNT3. The third contact hole CNT3 may be located in the first peripheral area PA1.

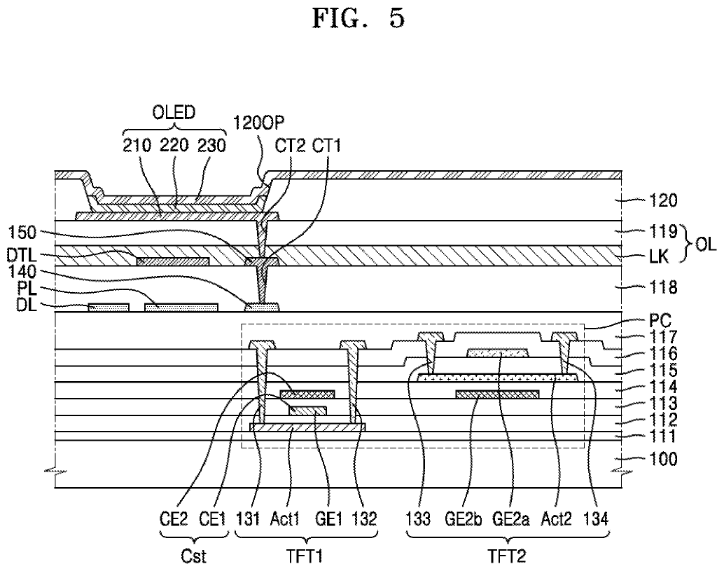

The first vertical connection line DV1, the first horizontal connection line DH1, and the first additional vertical connection line DV1′ may be integrally formed with one another. Similarly, the second vertical connection line DV2, the second horizontal connection line DH2, and the second additional vertical connection line DV2′ may be integrally formed with one another. The third vertical connection line DV3, the third horizontal connection line DH3, and the third additional vertical connection line DV3′ may be integrally formed with one another. In an embodiment, the first vertical connection line DV1 to the third vertical connection line DV3, the first horizontal connection line DH1 to the third horizontal connection line DH3, and the first additional vertical connection line DV1′ to the third additional vertical connection line DV3′ may be disposed on a layer different from a layer the first data line DL1 to the sixth data line DL6 are disposed. For example, the first data line DL1 to the sixth data line DL6, the driving voltage line (see, e.g., PL of FIG. 5), and a first connection electrode (see, e.g., 140 of FIG. 5) may be disposed on a same layer, and the first vertical connection line DV1 to the third vertical connection line DV3, the first horizontal connection line DH1 to the third horizontal connection line DH3, the first additional vertical connection line DV1′ to the third additional vertical connection line DV3′, and a second connection electrode (see, e.g., 150 of FIG. 5) may be disposed on a same layer.

Constituent elements being disposed on a same layer may mean that the constituent elements are simultaneously formed of a same material through a same mask process. The constituent elements may include a same material.

Referring to FIG. 3B, the first horizontal connection line DH1, the second horizontal connection line DH2, and the third horizontal connection line DH3 may be electrically connected to corresponding ones of the first vertical connection line DV1, the second vertical connection line DV2, and the third vertical connection line DV3, through a first connection contact hole DH-CNT1 located at an end of the first horizontal connection line DH1, the second horizontal connection line DH2, and the third horizontal connection line DH3. The first connection contact hole DH-CNT1 may be located in the display area DA. Furthermore, the first horizontal connection line DH1, the second horizontal connection line DH2, and the third horizontal connection line DH3 may be electrically connected to corresponding ones of the first additional vertical connection line DV1′, the second additional vertical connection line DV2′, and the third additional vertical connection line DV3′, respectively, through a second connection contact hole DH-CNT2 located at another end of the first horizontal connection line DH1, the second horizontal connection line DH2, and the third horizontal connection line DH3. The second connection contact hole DH-CNT2 may be located in the display area DA.

The first additional vertical connection line DV1′, the second additional vertical connection line DV2′, and the third additional vertical connection line DV3′ may be integrally formed and be electrically connected to corresponding ones of the second data line DL2, the fourth data line DL4, and the sixth data line DL6, respectively, in the first peripheral area PA1.

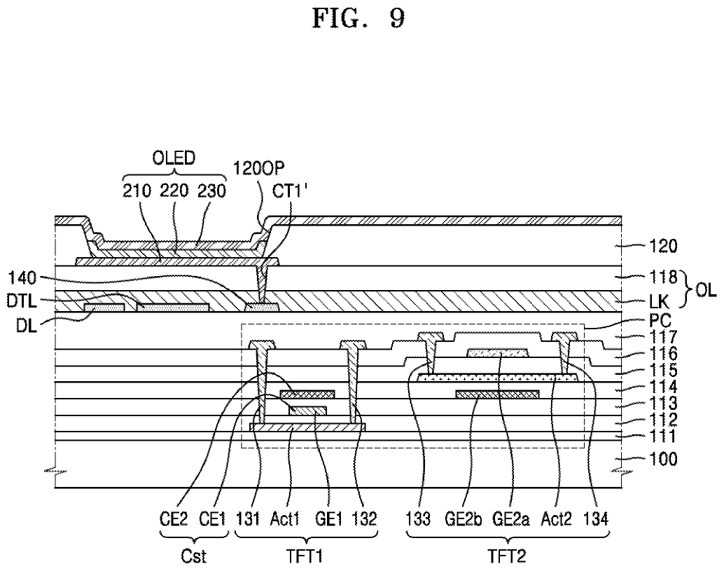

The first vertical connection line DV1 to the third vertical connection line DV3, the first additional vertical connection line DV1′ to the third additional vertical connection line DV3′, and the first data line DL1 to the sixth data line DL6 may be disposed on a same layer. The first horizontal connection line DH1 to the third horizontal connection line DH3 may be disposed on a layer different from a layer the first data line DL1 to the sixth data line DL6 are disposed. For example, the first vertical connection line DV1 to the third vertical connection line DV3, the first additional vertical connection line DV1′ to the third additional vertical connection line DV3′, and the data line (see, e.g., DL of FIG. 9) may be disposed on a same layer, and the first horizontal connection line DH1 to the third horizontal connection line DH3, a first source electrode (see, e.g., 131 of FIG. 9), a first drain electrode (see, e.g., 132 of FIG. 9), a second source electrode (see, e.g., 133 of FIG. 9), and a second drain electrode (see, e.g., 134 of FIG. 9) may be disposed on a same layer.

Referring to FIGS. 3A and 3B, in a plan view, the first horizontal connection line DH1 may intersect the first data line DL1, the second horizontal connection line DH2 may intersect the first data line DL1 to the third data line DL3, and the third horizontal connection line DH3 may intersect the first data line DL1 to the fifth data line DL5. Accordingly, to prevent the first horizontal connection line DH1 to the third horizontal connection line DH3 from contacting the data lines (e.g., the first data line DL1 to the sixth data line DL6), the first horizontal connection line DH1 to the third horizontal connection line DH3 may be located on and/or below the first data line DL1 to the sixth data line DL6.

FIG. 3A illustrates that the first horizontal connection line DH1 to the third horizontal connection line DH3 are located on the first data line DL1 to the sixth data line DL6. The first connection wire DTL1 to the third connection wire DTL3 may be disposed on an insulating layer (not shown) covering the first data line DL1 to the sixth data line DL6.

FIG. 3B illustrates that the first horizontal connection line DH1 to the third horizontal connection line DH3 are located below the first data line DL1 to the sixth data line DL6. The first data line DL1 to the sixth data line DL6 may be disposed on an insulating layer (not shown) covering the first horizontal connection line DH1 to the third horizontal connection line DH3.

As illustrated in FIG. 3B, the display apparatus according to an embodiment may further include dummy lines (e.g., ADH1, ADH2, ADH3, ADV1, ADV2, ADV3, ADV1′, ADV2′, and ADV3′).

Referring to FIG. 3B, the display apparatus according to an embodiment may include a first auxiliary horizontal connection line ADH1 that is spaced apart from the first horizontal connection line DH1, is electrically insulated from the first horizontal connection line DH1 and the second data line DL2, and colinear with the first horizontal connection line DH1. The display apparatus may include a first auxiliary horizontal connection line ADH1 located at a side of the first horizontal connection line DH1 (e.g., the −x direction) and a first auxiliary horizontal connection line ADH1 located at another side of the first horizontal connection line DH1 (e.g., the +x direction). Likewise, the display apparatus may include a second auxiliary horizontal connection line ADH2 located at a side of the second horizontal connection line DH2 (e.g., the −x direction), a second auxiliary horizontal connection line ADH2 located at another side of the second horizontal connection line DH2 (e.g., the +x direction), a third auxiliary horizontal connection line ADH3 located at a side of the third horizontal connection line DH3 (e.g., the −x direction), and a third auxiliary horizontal connection line ADH3 located at another side of the third horizontal connection line DH3 (e.g., the +x direction). The first auxiliary horizontal connection line ADH1, the second auxiliary horizontal connection line ADH2, and the third auxiliary horizontal connection line ADH3 may be electrically insulated from the first horizontal connection line DH1, the second horizontal connection line DH2, the third horizontal connection line DH3, and the data lines (e.g., the first data line DL1 to the sixth data line DL6).

Accordingly, a structural difference may be reduced between the sub-pixels PX through which the first horizontal connection line DH1 to the third horizontal connection line DH3 pass and the sub-pixels PX through which the first horizontal connection line DH1 to the third horizontal connection line DH3 do not pass. As a result, as a difference in luminance between sub-pixels PX is reduced in case that a same electrical signal is applied to the sub-pixels PX, and a display apparatus for displaying a high-quality image may be implemented. The first auxiliary horizontal connection line ADH1 to the third auxiliary horizontal connection line ADH3 and the first horizontal connection line DH1 to the third horizontal connection line DH3 may be disposed on a same layer.

In an embodiment, the display apparatus according to an embodiment may include a first auxiliary vertical connection line ADV1 that is spaced apart from the first vertical connection line DV1, is electrically insulated from the first vertical connection line DV1 and the first horizontal connection line DH1, is colinear with the first vertical connection line DV1, and is located at a side of the first vertical connection line DV1 (e.g., the +y direction). In an embodiment, the display apparatus may include a second auxiliary vertical connection line ADV2 located at a side of the second vertical connection line DV2 (e.g., the +y direction), and a third auxiliary vertical connection line ADV3 located at a side of the third vertical connection line DV3 (e.g., the +y direction). The first auxiliary vertical connection line ADV1 to the third auxiliary vertical connection line ADV3 and the first vertical connection line DV1 to the third vertical connection line DV3 may be disposed on a same layer.

In an embodiment, the display apparatus according to an embodiment may include a first additional auxiliary vertical connection line ADV1′ that is spaced apart from the first additional vertical connection line DV1′, is electrically insulated from the first additional vertical connection line DV1′ and a first horizontal connection line DH1′, is colinear with the first additional vertical connection line DV1′, and is located at a side of the first additional vertical connection line DV1′ (e.g., the +y direction). In an embodiment, the display apparatus may include a second additional auxiliary vertical connection line ADV2′ located at a side of the second additional vertical connection line DV2′ (e.g., the +y direction), and a third additional auxiliary vertical connection line ADV3′ located at a side of the third additional vertical connection line DV3′ (e.g., the +y direction). The first additional auxiliary vertical connection line ADV1′ to the third additional auxiliary vertical connection line ADV3′ and the first additional vertical connection line DV1′ to the third additional vertical connection line DV3′ may be disposed on a same layer.

Accordingly, a structural difference may be reduced between the sub-pixels PX through which the first vertical connection line DV1 to the third vertical connection line DV3 pass and the sub-pixels PX through which the first vertical connection line DV1 to the third vertical connection line DV3 do not pass. A structural difference may be reduced between the sub-pixels PX through which the first additional vertical connection line DV1′ to the third additional vertical connection line DV3′ pass and the sub-pixels PX through which the first additional vertical connection line DV1′ to the third additional vertical connection line DV3′ do not pass. As a result, as a difference in luminance implemented in sub-pixels PX in case that a same electrical signal is applied to the sub-pixels PX is reduced, and a display apparatus for displaying a high-quality image may be implemented.

FIGS. 4A and 4B are each schematic diagram of an equivalent circuit of a sub-pixel of a display apparatus according to an embodiment.

Referring to FIG. 4A, each sub-pixel PX may include a sub-pixel circuit PC electrically connected to the scan line SL and the data line DL and an organic light-emitting diode OLED electrically connected to the sub-pixel circuit PC.

The sub-pixel circuit PC may include a driving thin film transistor T1, a switching thin film transistor T2, and a storage capacitor Cst. The switching thin film transistor T2 may be electrically connected to the scan line SL and the data line DL, and may transmit a data signal input through the data line DL to the driving thin film transistor T1, in response to a scan signal input through the scan line SL.

The storage capacitor Cst may be electrically connected to the switching thin film transistor T2 and the driving voltage line PL, and may store a voltage corresponding to a difference between a voltage received from the switching thin film transistor T2 and the driving voltage ELVDD supplied from the driving voltage line PL.

The driving thin film transistor T1 may be electrically connected to the driving voltage line PL and the storage capacitor Cst, and may control a driving current Ioled flowing to the organic light-emitting diode OLED from the driving voltage line PL, in response to the voltage value stored in the storage capacitor Cst. The organic light-emitting diode OLED may emit light having a luminance (e.g., a certain or selectable luminance) according to the driving current Ioled.

Although FIG. 4A illustrates that the sub-pixel circuit PC includes two thin film transistors T1 and T2 and one storage capacitor Cst, the disclosure is not limited thereto. For example, the sub-pixel circuit PC may include three or more thin film transistors and/or two or more storage capacitors. In an embodiment, the sub-pixel circuit PC may include seven thin film transistors (see, e.g., T1 to T7 of FIG. 4B) and a storage capacitor (see, e.g., Cst of FIG. 4B).

Referring to FIG. 4B, a sub-pixel PX may include a sub-pixel circuit PC and an organic light-emitting diode OLED electrically connected to the sub-pixel circuit PC.

Referring to FIG. 4B, in an embodiment, the sub-pixel circuit PC may include multiple thin film transistors T1 to T7 and a storage capacitor Cst. The thin film transistors T1 to T7 and the storage capacitor Cst may be electrically connected to signal lines SL1, SL2, SLp, SLn, EL, and DL, an initialization voltage line VIL, and a driving voltage line PL. In an embodiment, at least one of the signal lines SL1, SL2, SLp, SLn, EL, and DL, for example, the initialization voltage line VIL or/and the driving voltage line PL, may be shared by the neighboring sub-pixels PX.

The thin film transistors T1 to T7 may include a driving thin film transistor T1, a switching thin film transistor T2, a compensation thin film transistor T3, a first initialization thin film transistor T4, an operation control thin film transistor T5, an emission control thin film transistor T6, and a second initialization thin film transistor T7.

Some of the thin film transistors T1 to T7 may be n-channel MOSFET (hereinafter, NMOS) transistors, and the other of the thin film transistors T1 to T7 may be p-channel MOSFET (hereinafter, PMOS) transistors. For example, among the thin film transistors T1 to T7, the compensation thin film transistor T3 and the first initialization thin film transistor T4 may be NMOS transistors, and the other (e.g., T1, T2, and T5 to T7 of thin film transistors T1 to T7) may be PMOS transistors. In another embodiment, among the thin film transistors T1 to T7, the compensation thin film transistor T3, the first initialization thin film transistor T4, and the second initialization thin film transistor T7 may be NMOS transistors, and the other (e.g., T1, T2, T5, and T6 of thin film transistors T1 to T7) may be PMOS transistors. In another embodiment, the thin film transistors T1 to T7 may all be NMOS transistors or all be PMOS transistors.

In the following description, an embodiment in which the compensation thin film transistor T3 and the first initialization thin film transistor T4 are NMOS transistors including oxide semiconductor, and the other (e.g., T1, T2, and T5 to T7 of thin film transistors T1 to T7) are PMOS transistors is described.

A signal line may include a first scan line SL1 for transmitting a first scan signal Sn, a second scan line SL2 for transmitting a second scan signal Sn′, a previous (or preceding) scan line SLp for transmitting a previous (or preceding) scan signal Sn−1 to the first initialization thin film transistor T4, the emission control line EL for transmitting an emission control signal En to the operation control thin film transistor T5 and the emission control thin film transistor T6, a next (or following) scan line SLn for transmitting a next (or following) scan signal Sn+1 to the second initialization thin film transistor T7, and the data line DL for transmitting a data signal Dm, the data line DL intersecting the first scan line SL1.

The driving voltage line PL may transmit the driving voltage ELVDD to the driving thin film transistor T1, and the initialization voltage line VIL may transmit an initialization voltage Vint for initializing the driving thin film transistor T1 and a sub-pixel electrode.

A driving gate electrode of the driving thin film transistor T1 may be electrically connected to the storage capacitor Cst, a driving source region of the driving thin film transistor T1 may be electrically connected to the driving voltage line PL through the operation control thin film transistor T5, and a driving drain region of the driving thin film transistor T1 may be electrically connected to a sub-pixel electrode of the organic light-emitting diode OLED through the emission control thin film transistor T6. The driving thin film transistor T1 may receive a data signal Dm and supply a driving current I_{OLED} to the organic light-emitting diode OLED, according to a switching operation of the switching thin film transistor T2.

A switching gate electrode of the switching thin film transistor T2 may be electrically connected to the first scan line SL1, a switching source region of the switching thin film transistor T2 may be electrically connected to the data line DL, a switching drain region of the switching thin film transistor T2 may be electrically connected to the driving source region of the driving thin film transistor T1 and to the driving voltage line PL through the operation control thin film transistor T5. The switching thin film transistor T2 may be turned on in response to the first scan signal Sn received through the first scan line SL1 and perform a switching operation of transmitting the data signal Dm transmitted through the data line DL to the driving source region of the driving thin film transistor T1.

A compensation gate electrode of the compensation thin film transistor T3 may be electrically connected to the second scan line SL2. A compensation drain region of the compensation thin film transistor T3 may be electrically connected to the driving drain region of the driving thin film transistor T1 and to the sub-pixel electrode of the organic light-emitting diode OLED through the emission control thin film transistor T6. A compensation source region of the compensation thin film transistor T3 may be electrically connected to a first capacitor electrode CE1 of the storage capacitor Cst and the driving gate electrode of the driving thin film transistor T1. Furthermore, the compensation source region of the compensation thin film transistor T3 may be electrically connected to a first initialization drain region of the first initialization thin film transistor T4.

The compensation thin film transistor T3 may be turned on in response to the second scan signal Sn′ received through the second scan line SL2 and electrically connect the driving gate electrode of the driving thin film transistor T1 to the driving drain region of the driving thin film transistor T1, thereby diode-connecting the driving thin film transistor T1.

A first initialization gate electrode of the first initialization thin film transistor T4 may be electrically connected to the previous scan line SLp. A first initialization source region of the first initialization thin film transistor T4 may be electrically connected to a second initialization source region of the second initialization thin film transistor T7 and the initialization voltage line VIL. The first initialization drain region of the first initialization thin film transistor T4 may be electrically connected to the first capacitor electrode CE1 of the storage capacitor Cst, the compensation source region of the compensation thin film transistor T3, and the driving gate electrode of the driving thin film transistor T1. The first initialization thin film transistor T4 may be turned on in response to the previous scan signal Sn−1 received through the previous scan line SLp and perform an initialization operation of initializing a voltage of the driving gate electrode of the driving thin film transistor T1 by transmitting the initialization voltage Vint to the driving gate electrode of the driving thin film transistor T1.

An operation control gate electrode of operation control thin film transistor T5 may be electrically connected to the emission control line EL, an operation control source region of the operation control thin film transistor T5 may be electrically connected to the driving voltage line PL, and an operation control drain region of the operation control thin film transistor T5 may be electrically connected to the driving source region of the driving thin film transistor T1 and the switching drain region of the switching thin film transistor T2.

An emission control gate electrode of the emission control thin film transistor T6 may be electrically connected to the emission control line EL, an emission control source region of the emission control thin film transistor T6 may be electrically connected to the driving drain region of the driving thin film transistor T1 and the compensation drain region of the compensation thin film transistor T3, and an emission control drain region of the emission control thin film transistor T6 may be electrically connected to a second initialization drain region of the second initialization thin film transistor T7 and the sub-pixel electrode of the organic light-emitting diode OLED.

The operation control thin film transistor T5 and the emission control thin film transistor T6 may be simultaneously turned on in response to the emission control signal En received through the emission control line EL, and as the driving voltage ELVDD is supplied to the organic light-emitting diode OLED, the driving current I_{OLED} may flow in the organic light-emitting diode OLED.

A second initialization gate electrode of the second initialization thin film transistor T7 may be electrically connected to the next scan line SLn, the second initialization drain region of the second initialization thin film transistor T7 may be electrically connected to the emission control drain region of the emission control thin film transistor T6 and the sub-pixel electrode of the organic light-emitting diode OLED, and the second initialization source region of the second initialization thin film transistor T7 may be electrically connected to the first initialization source region of the first initialization thin film transistor T4 and the initialization voltage line VIL. The second initialization thin film transistor T7 may be turned on in response to the next scan signal Sn+1 received through the next scan line SLn and initialize the sub-pixel electrode of the organic light-emitting diode OLED.

The second initialization thin film transistor T7 may be electrically connected to the next scan line SLn, as illustrated in FIG. 4B. In an embodiment, the second initialization thin film transistor T7 may be electrically connected to the emission control line EL and be driven according to the emission control signal En. Positions of the source regions and the drain regions may be switched according to the type (p-type or n-type) of the transistor.

The storage capacitor Cst may include the first capacitor electrode CE1 and a second capacitor electrode CE2. The first capacitor electrode CE1 of the storage capacitor Cst may be electrically connected to the driving gate electrode of the driving thin film transistor T1, and the second capacitor electrode CE2 of the storage capacitor Cst may be electrically connected to the driving voltage line PL. The storage capacitor Cst may store electric charges corresponding to a difference between the voltage of the driving gate electrode of the driving thin film transistor T1 and the driving voltage ELVDD.

An operation of each sub-pixel PX according to an embodiment is described as follows.

During an initialization period, when the previous scan signal Sn−1 is supplied through the previous scan line SLp, the first initialization thin film transistor T4 may be turned on in response to the previous scan signal Sn−1, and the driving thin film transistor T1 may be initialized by the initialization voltage Vint supplied through the initialization voltage line VIL.

During a data programming period, when the first scan signal Sn and the second scan signal Sn′ are supplied through the first scan line SL1 and the second scan line SL2, respectively, the switching thin film transistor T2 and the compensation thin film transistor T3 may be turned on in response to the first scan signal Sn and the second scan signal Sn′. By the compensation thin film transistor T3 that is turned on, the driving thin film transistor T1 may be diode-connected and biased in a forward direction.

A compensation voltage (Dm+Vth), where Vth may be a (−) value, which is obtained by deducting the threshold voltage Vth of the driving thin film transistor T1 from the data signal Dm supplied through the data line DL, may be applied to a driving gate electrode of the driving thin film transistor T1.

The driving voltage ELVDD and the compensation voltage (Dm+Vth) may be applied to both ends of the storage capacitor Cst, and the storage capacitor Cst may store electric charges corresponding to the voltage difference of the both ends.

During a light-emitting period, the operation control thin film transistor T5 and the emission control thin film transistor T6 may be turned on in response to the emission control signal En supplied through the emission control line EL. The driving current I_{OLED} according to the voltage difference between the voltage of the driving gate electrode of the driving thin film transistor T1 and the driving voltage ELVDD may be generated, and the driving current I_{OLED} may be supplied to the organic light-emitting diode OLED through the emission control thin film transistor T6.

In an embodiment, at least one of the thin film transistors T1 to T7 may include an oxide semiconductor layer, and the other of the thin film transistors T1 to T7 may include a silicon semiconductor layer.

For example, the driving thin film transistor T1 that has an effect (e.g., a direct effect) on a brightness of the display apparatus may include a semiconductor layer including polycrystalline silicon having high reliability, and accordingly, the display apparatus of a high resolution may be implemented.

As oxide semiconductor has high carrier mobility and low leakage current, even in case that a driving time is long, a voltage drop may not be much. For example, as a color change of an image according to a voltage drop is not much during low frequency driving, low frequency driving may be possible.

As such, as oxide semiconductor has a merit of low leakage current, by employing at least one of the compensation thin film transistor T3, the first initialization thin film transistor T4, and the second initialization thin film transistor T7, which are electrically connected to the driving gate electrode of the driving thin film transistor T1, as oxide semiconductor, a leakage current that may flow to the driving gate electrode may be prevented and simultaneously power consumption may be reduced.

FIG. 5 is a schematic cross-sectional view of a portion of a display area in which a connection wire is arranged, of a display apparatus according to an embodiment.

Referring to FIG. 5, the display apparatus may include a connection wire DTL that passes through the display area DA. The connection wire DTL may be the first connection wire DTL1, the second connection wire DTL2, or the third connection wire DTL3, which are described with reference to FIG. 2A. For example, the connection wire DTL may be the first vertical connection line DV1 to third vertical connection line DV3 or the first additional vertical connection line DV1′ to third additional vertical connection line DV3′ of the first connection wire DTL1 to third connection wire DTL3.

In the display area DA through which the connection wire DTL passes, the display apparatus may include the substrate 100, the sub-pixel circuit PC, and the organic light-emitting diode OLED as a light-emitting element. Multiple insulating layers may be disposed on and/or below constituent element of the thin film transistor TFT1 and TFT2 and the capacitor Cst constituting the sub-pixel circuit PC.

The sub-pixel circuit PC may include at least one thin film transistor and at least one capacitor. FIG. 5 illustrates a first thin film transistor TFT1, a second thin film transistor TFT2, and the storage capacitor Cst among at least one thin film transistor and at least one capacitor in the sub-pixel circuit PC. The first thin film transistor TFT1 may include a first semiconductor layer Act1, a first gate electrode GE1, the first source electrode 131, and the first drain electrode 132. The second thin film transistor TFT2 may include a second semiconductor layer Act2, an upper second gate electrode GE2a, a lower second gate electrode GE2b, the second source electrode 133, and the second drain electrode 134. The storage capacitor Cst may include the first capacitor electrode CE1 and the second capacitor electrode CE2.

The insulating layers may include inorganic insulating layers and organic insulating layers. The inorganic insulating layers may include a buffer layer 111, a first gate insulating layer 112, a first interlayer insulating layer 113, a second interlayer insulating layer 114, a second gate insulating layer 115, and a third interlayer insulating layer 116. The organic insulating layers may include a first organic insulating layer 117, a second organic insulating layer 118, a third organic insulating layer 119, and a low-k dielectric layer LK.

The buffer layer 111 may be disposed on the substrate 100. The buffer layer 111 may have a single layer or multilayer structure including an inorganic insulating material, such as a silicon oxide, a silicon nitride, a silicon oxynitride, the like, or a combination thereof. The insulating layers may further include another barrier layer (not shown) for preventing infiltration of external air between the substrate 100 and the buffer layer 111. In an embodiment, the buffer layer 111 may be omitted.

At least one of the first semiconductor layer Act1 and the second semiconductor layer Act2 may include oxide semiconductor. In an embodiment, the first semiconductor layer Act1 may include silicon semiconductor or the like, and the second semiconductor layer Act2 may include oxide semiconductor or the like. The first semiconductor layer Act1 and the second semiconductor layer Act2 may each include a channel region, and a source region and a drain region arranged at each side of the channel region.

The first semiconductor layer Act1 may be arranged between the buffer layer 111 and the first gate insulating layer 112. In an embodiment, the first semiconductor layer Act1 may include silicon semiconductor or the like. For example, the first semiconductor layer Act1 may include polysilicon, amorphous silicon, the like, or a combination thereof.

The first gate insulating layer 112 may include a silicon oxide, a silicon nitride, a silicon oxynitride, an aluminum oxide, a titanium oxide, a tantalum oxide, a hafnium oxide, a zinc oxide, the like, or a combination thereof.

The first gate electrode GE1 may be disposed between the first gate insulating layer 112 and the first interlayer insulating layer 113. The first gate electrode GE1 may include a conductive material such as molybdenum (Mo), aluminum (Al), copper (Cu), titanium (Ti), the like, or an alloy thereof, and may be provided in a multilayer or single layer. In an embodiment, the first capacitor electrode CE1 may be integrally formed with the first gate electrode GEL. The second capacitor electrode CE2 may be disposed on the first interlayer insulating layer 113, and may overlap the first capacitor electrode CE1 in a plan view.

The first interlayer insulating layer 113 may include an inorganic insulating material, such as a silicon oxide, a silicon nitride, a silicon oxynitride, an aluminum oxide, a titanium oxide, a tantalum oxide, a hafnium oxide, a zinc oxide, the like, or a combination thereof. The second capacitor electrode CE2 may include a conductive material such as Mo, Al, Cu, Ti, the like, or an alloy thereof, and may be provided in a multilayer or single layer.

Referring to FIG. 5, the first capacitor electrode CE1 may overlap the first thin film transistor TFT1 in a plan view. For example, the first gate electrode GE1 may perform a function of the first capacitor electrode CE1 of the storage capacitor Cst. However, the disclosure is not limited thereto, and in another embodiment, the storage capacitor Cst may be separate from the first thin film transistor TFT1.

The second interlayer insulating layer 114 may be disposed on the second capacitor electrode CE2 and the first interlayer insulating layer 113. The second interlayer insulating layer 114 may include an inorganic insulating material, such as a silicon oxide, a silicon nitride, a silicon oxynitride, an aluminum oxide, a titanium oxide, a tantalum oxide, a hafnium oxide, a zinc oxide, the like, or a combination thereof.

The second semiconductor layer Act2 may be disposed on the second interlayer insulating layer 114. In an embodiment, the second semiconductor layer Act2 may include oxide semiconductor or the like. For example, the second semiconductor layer Act2 may include a Zn oxide-based material, such as a Zn oxide, an In—Zn oxide, a Ga—In—Zn oxide, the like, or a combination thereof. In another embodiment, the second semiconductor layer Act2 may include In-Ga—Zn-O (IGZO), In—Sn—Zn—O (ITZO), or In—Ga—Sn—Zn—O (IGTZO) semiconductor, in which metal such as indium (In), gallium (Ga), tin (Sn), the like, and/or an alloy thereof is included in a zinc oxide.

The second gate insulating layer 115 may be disposed on the second semiconductor layer Act2 and the second interlayer insulating layer 114. In an embodiment, the second gate insulating layer 115 may include an inorganic insulating material, such as a silicon oxide, a silicon nitride, a silicon oxynitride, an aluminum oxide, a titanium oxide, a tantalum oxide, a hafnium oxide, a zinc oxide, the like, or a combination thereof.

The upper second gate electrode GE2a may be disposed on the second gate insulating layer 115. The upper second gate electrode GE2a may overlap the second semiconductor layer Act2 in a plan view, and may be arranged between the second gate insulating layer 115 and the third interlayer insulating layer 116. The upper second gate electrode GE2a may include a conductive material such as Mo, Al, Cu, Ti, the like, and an alloy thereof, and may be provided in a multilayer or single layer.

The lower second gate electrode GE2b may be disposed below the second semiconductor layer Act2. In an embodiment, the lower second gate electrode GE2b may be arranged between the first interlayer insulating layer 113 and the second interlayer insulating layer 114. In an embodiment, the lower second gate electrode GE2b may receive a gate signal, and the second thin film transistor TFT2 may have a dual gate electrode structure in which gate electrodes are arranged on and below the second semiconductor layer Act2. The lower second gate electrode GE2b and the second capacitor electrode CE2 may be disposed on a same layer and may include a same material.

The first source electrode 131, the first drain electrode 132, the second source electrode 133, and the second drain electrode 134 may be disposed on the third interlayer insulating layer 116. In an embodiment, the third interlayer insulating layer 116 may include an inorganic insulating material, such as a silicon oxide, a silicon nitride, a silicon oxynitride, an aluminum oxide, a titanium oxide, a tantalum oxide, a hafnium oxide, a zinc oxide, the like, or a combination thereof.

The first source electrode 131, the first drain electrode 132, the second source electrode 133, and the second drain electrode 134 may each include a conductive material such as Mo, Al, Cu, Ti, the like, and an alloy thereof, and may be formed in a multilayer or single layer. In an embodiment, the first source electrode 131, the first drain electrode 132, the second source electrode 133, and the second drain electrode 134 may each have a multilayer structure of Ti/Al/Ti.

The first source electrode 131 and the first drain electrode 132 may be electrically connected to the first semiconductor layer Act1 through contact holes of the insulating layers. The second source electrode 133 and the second drain electrode 134 may be electrically connected to the second semiconductor layer Act2 through the contact holes of the insulating layers.

The organic insulating layers may be disposed on the inorganic insulating layers, the first source electrode 131, the first drain electrode 132, the second source electrode 133, and the second drain electrode 134. In an embodiment, the organic insulating layers may include the first organic insulating layer 117, the second organic insulating layer 118, the third organic insulating layer 119, and the low-k dielectric layer LK.

The first connection electrode 140 may be disposed on the first organic insulating layer 117. Although not illustrated, the first connection electrode 140 may be electrically connected to the sub-pixel circuit PC through a contact hole (not shown) of the first organic insulating layer 117. The data line DL and the driving voltage line PL may be disposed on the first organic insulating layer 117. The first connection electrode 140, the data line DL, and the driving voltage line PL may include a conductive material such as Mo, Al, Cu, Ti, the like, and an alloy thereof, and may be formed in a multilayer or single layer.

The second organic insulating layer 118 may cover the first connection electrode 140, the data line DL, the driving voltage line PL, and the first organic insulating layer 117.

The second connection electrode 150 may be disposed on the second organic insulating layer 118. The second connection electrode 150 may be electrically connected to the first connection electrode 140 through a contact hole CT1 of the second organic insulating layer 118. The connection wire DTL may be disposed on the second organic insulating layer 118. The connection wire DTL may overlap a sub-pixel electrode 210 in a plan view.

The second connection electrode 150 and the connection wire DTL may each include a conductive material such as Mo, Al, Cu, Ti, the like, and an alloy thereof, and may be formed in a multilayer or single layer.

An insulating layer OL may cover the second connection electrode 150 and the connection wire DTL. The sub-pixel electrode 210 of the organic light-emitting diode OLED may be disposed on the insulating layer OL. The connection wire DTL may overlap the sub-pixel electrode 210 in a plan view with the insulating layer OL disposed between the sub-pixel electrode 210 and the connection wire DTL. The insulating layer OL may include the low-k dielectric layer LK and the third organic insulating layer 119. The low-k dielectric layer LK may cover the connection wire DTL. The third organic insulating layer 119 may be disposed on the low-k dielectric layer LK. For example, in the insulating layer OL, the low-k dielectric layer LK may be disposed below the third organic insulating layer 119. In an embodiment, the low-k dielectric layer LK may be a first insulating layer. In an embodiment, the third organic insulating layer 119 may be a second insulating layer.

The low-k dielectric layer LK may include a material having a lower dielectric constant than a dielectric constant of the third organic insulating layer 119. The low-k dielectric layer LK may include an organic material. In an embodiment, the low-k dielectric layer LK may include benzocyclobutene (BCB) or the like. In an embodiment, a surface of the low-k dielectric layer LK may be hydrophobic or hydrophilic.

The dielectric constant of the low-k dielectric layer LK may be less than a dielectric constant of the third organic insulating layer 119. In an embodiment, the dielectric constant of the low-k dielectric layer LK may be less than about 3. In an embodiment, the dielectric constant of the low-k dielectric layer LK may be less than about 2.8. In an embodiment, the dielectric constant of the low-k dielectric layer LK may be in a range of about 2.5 to about 2.7.

The third organic insulating layer 119 may include a material having a higher dielectric constant than the dielectric constant of the low-k dielectric layer LK. The third organic insulating layer 119 may include an organic material. In an embodiment, the third organic insulating layer 119 may include photosensitive polyimide (PSPI) or the like. As the third organic insulating layer 119 includes a material having a higher dielectric constant than the dielectric constant of the low-k dielectric layer LK, a chemical resistance of the insulating layer OL may be improved. Accordingly, in a process of forming the sub-pixel electrode 210 on the insulating layer OL, for example, the third organic insulating layer 119, a possibility of the insulating layer OL being exposed to chemicals so that defects are generated may be reduced.

In an embodiment, the dielectric constant of the third organic insulating layer 119 may be greater than about 3. In an embodiment, the dielectric constant of the third organic insulating layer 119 may be greater than about 3.2. In an embodiment, the dielectric constant of the third organic insulating layer 119 may be in a range of about 3.5 to about 5.

In an embodiment, a roughness of an upper surface of the third organic insulating layer 119 and a roughness of an upper surface of the low-k dielectric layer LK may be different from each other. In an embodiment, the roughness of the upper surface of the third organic insulating layer 119 may be greater than the roughness of the upper surface of the low-k dielectric layer LK. In an embodiment, the roughness of the upper surface of the low-k dielectric layer LK may be less than about 1 nm. In an embodiment, the roughness of the upper surface of the third organic insulating layer 119 may be greater than about 2 nm.

As the connection wire DTL passes through the display area DA, in a partial area of the display area DA, the connection wire DTL may overlap the sub-pixel electrode 210 of the organic light-emitting diode OLED in a plan view. A parasitic capacitance may be formed between the connection wire DTL and the sub-pixel electrode 210 overlapping each other in a plan view, and the insulating layer OL may function as a dielectric layer. As the connection wire DTL is electrically connected to the data line DL and transmit the data signal Dm, as described above with reference to FIG. 3A, the parasitic capacitance may prevent transmission of an accurate data signal, and a quality of an image displayed in the display area DA may be deteriorated.

However, in an embodiment, as the insulating layer OL between the connection wire DTL and the sub-pixel electrode 210 includes multiple layers, for example, the low-k dielectric layer LK and the third organic insulating layer 119, compared with an embodiment in which only one layer, for example, the third organic insulating layer 119, is included, a thickness of the insulating layer OL may be increased, and as the low-k dielectric layer LK in the insulating layer OL includes a material having a low dielectric constant, the parasitic capacitance between the connection wire DTL and the sub-pixel electrode 210 may be reduced. Accordingly, the image quality of the display area DA may be improved.

Furthermore, in case that the low-k dielectric layer LK includes BCB or the like, a moisture absorption rate may be very low, and accordingly, even in case that the thickness of the insulating layer OL increases as the insulating layer OL includes the low-k dielectric layer LK and the third organic insulating layer 119, a defect such as pixel shrinkage due to outgassing and the like may be prevented. Accordingly, the reliability of a display apparatus may be maintained.

The organic light-emitting diode OLED may be disposed on the insulating layer OL. The organic light-emitting diode OLED may include the sub-pixel electrode 210, an emission layer 220, and a counter electrode 230. The sub-pixel electrode 210 may be disposed on the insulating layer OL.

The sub-pixel electrode 210 may be electrically connected to the second connection electrode 150 through a contact hole CT2 that passes through the insulating layer OL, for example, the low-k dielectric layer LK and the third organic insulating layer 119. As described above, as the second connection electrode 150 is electrically connected to the first connection electrode 140 through the contact hole CT1 penetrating the second organic insulating layer 118, and the first connection electrode 140 is electrically connected to the sub-pixel circuit PC through the contact hole penetrating the first organic insulating layer 117, the sub-pixel electrode 210 may be electrically connected to the sub-pixel circuit PC through the first connection electrode 140 and the second connection electrode 150. For example, the sub-pixel electrode 210 may be electrically connected to the source electrode or drain electrode of the first thin film transistor TFT1 or the second thin film transistor TFT2 in the sub-pixel circuit PC.

The sub-pixel electrode 210 may include a reflective film (not shown) including silver (Ag), magnesium (Mg), Al, platinum (Pt), palladium (Pd), gold (Au), nickel (Ni), neodymium (Nd), iridium (Ir), chromium (Cr), the like, or an alloy thereof. In another embodiment, the sub-pixel electrode 210 may further include a conductive oxide layer (not shown) on and/or below the reflective film. The conductive oxide layer may include an indium tin oxide (ITO), an indium zinc oxide (IZO), a zinc oxide (ZnO), an indium oxide (In₂O₃), an indium gallium oxide (IGO), an aluminum zinc oxide (AZO), the like, or a combination thereof. In an embodiment, the sub-pixel electrode 210 may have a triple layer structure of ITO/Ag/ITO.

A bank layer 120 covering an edge of the sub-pixel electrode 210 may be disposed on the third organic insulating layer 119. An opening 1200P for exposing a portion of the sub-pixel electrode 210 may be defined in the bank layer 120. The opening 1200P of the bank layer 120 may define an emission area of a sub-pixel PX. The bank layer 120 may include an organic material or inorganic material.

The emission layer 220 may include a low molecular weight or polymer organic material. At least one of a hole injection layer (HIL), a hole transport layer (HTL), an electron transport layer (ETL), and an electron injection layer (EIL) may be further arranged between the sub-pixel electrode 210 and the counter electrode 230.

The counter electrode 230 may be disposed on the emission layer 220. The counter electrode 230 may include a conductive material having a low work function. For example, the counter electrode 230 may include a (semi-)transparent layer including Ag, Mg, Al, Pt, Pd, Au, Ni, Nd, Ir, Cr, lithium (Li), calcium (Ca), the like, or an alloy thereof. In an embodiment, the counter electrode 230 may further include a layer including ITO, IZO, ZnO, or In₂O₃ on the (semi-)transparent layer. In an embodiment, the counter electrode 230 may cover (e.g., entirely cover) the display area DA.

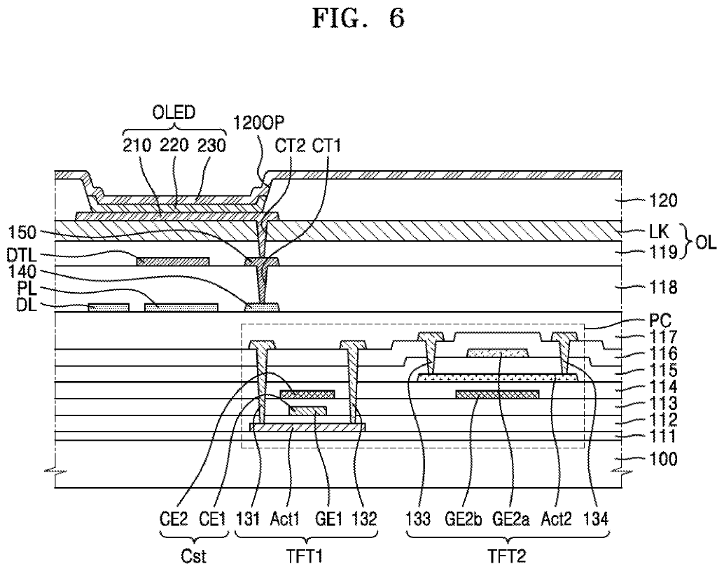

FIG. 6 is a schematic cross-sectional view of a portion of a display area in which a connection wire is arranged, of a display apparatus according to an embodiment. FIG. 6 illustrates a modified embodiment of FIG. 5, and the configuration of the organic insulating layers of FIG. 5 and the configuration of the organic insulating layers of FIG. 6 are different from each other. In the following description, only differences are described and redundant descriptions are omitted.

FIG. 5 illustrates that the insulating layer OL arranged between the connection wire DTL and the sub-pixel electrode 210 includes the low-k dielectric layer LK and the third organic insulating layer 119 on the low-k dielectric layer LK, but the disclosure is not limited thereto. Referring to FIG. 6, the insulating layer OL may include a third organic insulating layer 119 and a low-k dielectric layer LK disposed on the third organic insulating layer 119. The sub-pixel electrode 210 of the organic light-emitting diode OLED may be disposed on the low-k dielectric layer LK. For example, in the insulating layer OL, the low-k dielectric layer LK may be arranged on the third organic insulating layer 119. In an embodiment, the third organic insulating layer 119 may be a first insulating layer. In an embodiment, the low-k dielectric layer LK may be a second insulating layer.

The low-k dielectric layer LK may include a material having a lower dielectric constant than the dielectric constant of the third organic insulating layer 119. The low-k dielectric layer LK may include an organic material. In an embodiment, the low-k dielectric layer LK may include BCB or the like. In an embodiment, the low-k dielectric layer LK may include BCB having a hydrophobic functional group, and the surface of the low-k dielectric layer LK may be hydrophobic. Accordingly, generation of a pixel defect as moisture is introduced through the low-k dielectric layer LK on which the organic light-emitting diode OLED is disposed, may be prevented.

In an embodiment, the low-k dielectric layer LK may further include a photosensitive material. For example, the low-k dielectric layer LK may further include a photo active compound (PAC) or a photo acid generator (PAG).

The dielectric constant of the low-k dielectric layer LK may be less than the dielectric constant of the third organic insulating layer 119. In an embodiment, the dielectric constant of the low-k dielectric layer LK may be less than about 3. In an embodiment, the dielectric constant of the low-k dielectric layer LK may be less than about 2.8. In an embodiment, the dielectric constant of the low-k dielectric layer LK may be in a range of about 2.5 to about 2.7.

The third organic insulating layer 119 may include a material having a higher dielectric constant than the dielectric constant of the low-k dielectric layer LK. The third organic insulating layer 119 may include an organic material. For example, the third organic insulating layer 119 may include PSPI or the like.

In an embodiment, the dielectric constant of the third organic insulating layer 119 may be greater than about 3. In an embodiment, the dielectric constant of the third organic insulating layer 119 may be greater than about 3.2. In an embodiment, the dielectric constant of the third organic insulating layer 119 may be in a range of about 3.5 to about 5.

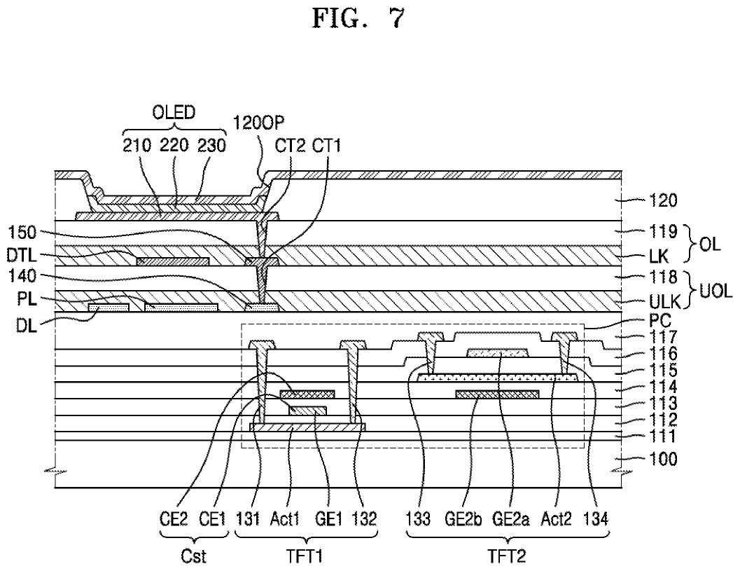

FIG. 7 is a schematic cross-sectional view of a portion of a display area in which a connection wire is arranged, of a display apparatus according to an embodiment. FIG. 7 illustrates a modified embodiment of FIG. 5, and the configuration of the organic insulating layers of FIG. 7 and the configuration of the organic insulating layers of FIG. 5 are different from each other. In the following description, only differences are described and redundant descriptions are omitted.

FIG. 5 illustrates that the insulating layer OL arranged between the connection wire DTL and the sub-pixel electrode 210 includes the low-k dielectric layer LK. Referring to FIG. 7, an under insulating layer UOL additionally arranged between the data line DL and the connection wire DTL may include a under low-k dielectric layer ULK.

The under insulating layer UOL may cover the data line DL, the driving voltage line PL, and the first connection electrode 140. The under insulating layer UOL may include an under low-k dielectric layer ULK and the second organic insulating layer 118 disposed on the under low-k dielectric layer ULK. In the under insulating layer UOL, the under low-k dielectric layer ULK may be arranged below the second organic insulating layer 118.

The connection wire DTL and the second connection electrode 150 may be disposed on the under insulating layer UOL. The second connection electrode 150 may be electrically connected to the first connection electrode 140 through the contact hole CT1 that penetrates the under insulating layer UOL, for example, the low-k dielectric layer LK and the second organic insulating layer 118.

The under low-k dielectric layer ULK of the under insulating layer UOL may have a lower dielectric constant than a dielectric constant of the second organic insulating layer 118. The under low-k dielectric layer ULK and the second organic insulating layer 118 of the under insulating layer UOL may respectively have the properties corresponding to the low-k dielectric layer LK and the third organic insulating layer 119 of the insulating layer OL described above in FIG. 5.

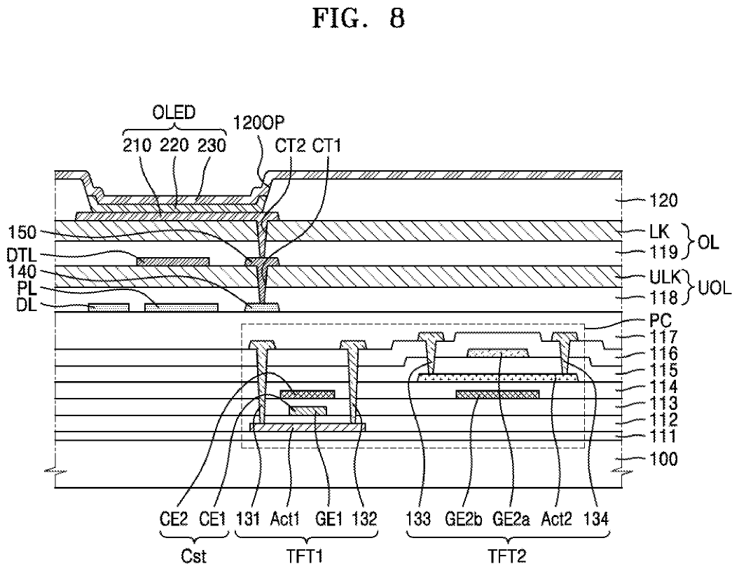

FIG. 8 is a schematic cross-sectional view of a portion of a display area in which a connection wire is arranged, of a display apparatus according to an embodiment. FIG. 8 illustrates a modified embodiment of FIG. 6, and the configuration of the organic insulating layers of FIG. 8 and the configuration of the organic insulating layers of FIG. 6 are different from each other. In the following description, only differences are described and redundant descriptions are omitted.

FIG. 6 illustrates that the insulating layer OL arranged between the connection wire DTL and the sub-pixel electrode 210 includes the low-k dielectric layer LK. Referring to FIG. 8, the under insulating layer UOL that is additionally arranged between the data line DL and the connection wire DTL may also include the under low-k dielectric layer ULK.

The under insulating layer UOL may cover the data line DL, the driving voltage line PL, and the first connection electrode 140. The under insulating layer UOL may include the second organic insulating layer 118 and the under low-k dielectric layer ULK on the second organic insulating layer 118. In the under insulating layer UOL, the under low-k dielectric layer ULK may be arranged on the second organic insulating layer 118.

The connection wire DTL and the second connection electrode 150 may be disposed on the under insulating layer UOL. The second connection electrode 150 may be electrically connected to the first connection electrode 140 through the contact hole CT1 that penetrates the under insulating layer UOL, for example, the under low-k dielectric layer ULK and the second organic insulating layer 118.

The under low-k dielectric layer ULK of the under insulating layer UOL may have a lower dielectric constant than the dielectric constant of the second organic insulating layer 118. The second organic insulating layer 118 and the under low-k dielectric layer ULK of the under insulating layer UOL may respectively have the properties corresponding to the third organic insulating layer 119 and the low-k dielectric layer LK of the insulating layer OL described above in FIG. 6.

FIG. 9 is a schematic cross-sectional view of a portion of a display area in which a connection wire is arranged, of a display apparatus according to an embodiment. FIG. 9 illustrates a modified embodiment of FIG. 5, in which the configurations of the organic insulating layers and the connection wire DTL of FIG. 5 and the configurations of the organic insulating layers and the connection wire DTL of FIG. 9 are different from each other. In the following description, only differences are described and redundant descriptions are omitted.

Referring to FIG. 9, the display apparatus may include the connection wire DTL that passes through the display area DA. The connection wire DTL may be the first connection wire DTL1, the second connection wire DTL2, or the third connection wire DTL3, which are described with reference to FIG. 3B. For example, the connection wire DTL may be the first vertical connection line DV1 to third vertical connection line DV3 or the first additional vertical connection line DV1′ to third additional vertical connection line DV3′ of the first connection wire DTL1 to third connection wire DTL3, which are described with reference to FIG. 3B. In an embodiment, the connection wire DTL and the data line DL may be disposed on a same layer.

In the display area DA through which the connection wire DTL passes, the display apparatus may include the substrate 100, the sub-pixel circuit PC, and the organic light-emitting diode OLED as a light-emitting element. Multiple insulating layers may be located on and/or below the constituent elements of the thin film transistors and the capacitor of the sub-pixel circuit PC.

FIG. 9 illustrates the first thin film transistor TFT1, the second thin film transistor TFT2, and the storage capacitor Cst among at least one thin film transistor and at least one capacitor in the sub-pixel circuit PC. The sub-pixel circuit PC may include the first thin film transistor TFT1, the second thin film transistor TFT2, and the storage capacitor Cst.

The insulating layers may include inorganic insulating layers and organic insulating layers. The inorganic insulating layers may include the buffer layer 111, the first gate insulating layer 112, the first interlayer insulating layer 113, the second interlayer insulating layer 114, the second gate insulating layer 115, and the third interlayer insulating layer 116. The organic insulating layers may be disposed on the inorganic insulating layers, the first source electrode 131, the first drain electrode 132, the second source electrode 133, and the second drain electrode 134. In an embodiment, the organic insulating layers may include the first organic insulating layer 117, the second organic insulating layer 118, and the low-k dielectric layer LK.

The first connection electrode 140 may be disposed on the first organic insulating layer 117. Although not illustrated, the first connection electrode 140 may be electrically connected to the sub-pixel circuit PC through the contact hole of the first organic insulating layer 117. Furthermore, the data line DL and the connection wire DTL may be disposed on the first organic insulating layer 117.

Referring to FIG. 9, the insulating layer OL may cover the first connection electrode 140, the data line DL, and the connection wire DTL. The sub-pixel electrode 210 of the organic light-emitting diode OLED may be disposed on the insulating layer OL. The connection wire DTL may overlap the sub-pixel electrode 210 with the insulating layer OL between the sub-pixel electrode 210 and the connection wire DTL in a plan view.

The insulating layer OL may include the low-k dielectric layer LK and the second organic insulating layer 118. The insulating layer OL may include the low-k dielectric layer LK and the second organic insulating layer 118 on the low-k dielectric layer LK. The organic light-emitting diode OLED may be disposed on the second organic insulating layer 118. For example, in the insulating layer OL, the low-k dielectric layer LK may be arranged below the second organic insulating layer 118. In an embodiment, the low-k dielectric layer LK may be a first insulating layer. In an embodiment, the second organic insulating layer 118 may be a second insulating layer.

The low-k dielectric layer LK and the second organic insulating layer 118 of FIG. 9 may have respectively have the properties corresponding to the low-k dielectric layer LK and the third organic insulating layer 119 of FIG. 5.

The low-k dielectric layer LK may include a material having a lower dielectric constant than the dielectric constant of the second organic insulating layer 118. The low-k dielectric layer LK may include an organic material. In an embodiment, the low-k dielectric layer LK may include BCB or the like. In an embodiment, the surface of the low-k dielectric layer LK may be hydrophobic or hydrophilic.

The low-k dielectric layer LK may have a lower dielectric constant than the second organic insulating layer 118. In an embodiment, the dielectric constant of the low-k dielectric layer LK may be less than about 3. In an embodiment, the dielectric constant of the low-k dielectric layer LK may be less than about 2.8. In an embodiment, the dielectric constant of the low-k dielectric layer LK may be in a range of about 2.5 to about 2.7.

The second organic insulating layer 118 may include a material having a higher dielectric constant than the dielectric constant of the low-k dielectric layer LK. The second organic insulating layer 118 may include an organic material. In an embodiment, the second organic insulating layer 118 may include PSPI or the like.

In an embodiment, the dielectric constant of the second organic insulating layer 118 may be greater than about 3. In an embodiment, the dielectric constant of the second organic insulating layer 118 may be greater than about 3.2. In an embodiment, the dielectric constant of the second organic insulating layer 118 may be in a range of about 3.5 to about 5.

In an embodiment, the roughness of an upper surface of the second organic insulating layer 118 and the roughness of the upper surface of the low-k dielectric layer LK may be different from each other. In an embodiment, the roughness of the upper surface of the second organic insulating layer 118 may be greater than the roughness of the upper surface of the low-k dielectric layer LK.

The organic light-emitting diode OLED may be disposed on the insulating layer OL. The sub-pixel electrode 210 may be electrically connected to the first connection electrode 140 through a contact hole CT1′ that penetrates the insulating layer OL, for example, the low-k dielectric layer LK and the second organic insulating layer 118. The sub-pixel electrode 210 may be electrically connected to the sub-pixel circuit PC through the first connection electrode 140.

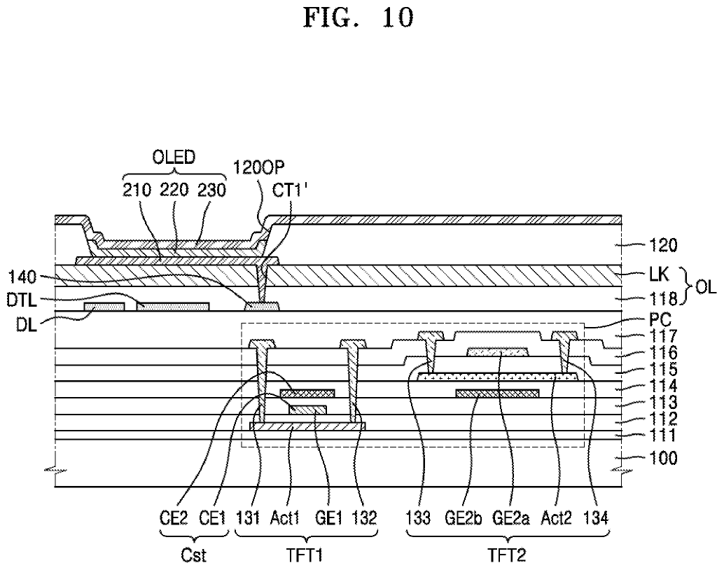

FIG. 10 is a schematic cross-sectional view of a portion of a display area in which a connection wire is arranged, of a display apparatus according to an embodiment. FIG. 10 illustrates a modified embodiment of FIG. 9, and the configuration of the organic insulating layers of FIG. 9 and the configuration of the organic insulating layers of FIG. 10 are different from each other. In the following description, only differences are described and redundant descriptions are omitted.

Referring to FIG. 10, the insulating layer OL may include the second organic insulating layer 118 and the low-k dielectric layer LK on the second organic insulating layer 118. The sub-pixel electrode 210 of the organic light-emitting diode OLED may be disposed on the low-k dielectric layer LK. For example, in the insulating layer OL, the low-k dielectric layer LK may be arranged on the second organic insulating layer 118. In an embodiment, the second organic insulating layer 118 may be a first insulating layer. In an embodiment, the low-k dielectric layer LK may be a second insulating layer.

The second organic insulating layer 118 and the low-k dielectric layer LK of FIG. 10 may respectively have the properties corresponding to the third organic insulating layer 119 and the low-k dielectric layer LK of FIG. 6.

The low-k dielectric layer LK may include a material having a lower dielectric constant than the dielectric constant of the second organic insulating layer 118. The low-k dielectric layer LK may include an organic material. In an embodiment, the low-k dielectric layer LK may include BCB or the like. In an embodiment, the low-k dielectric layer LK may include BCB having a hydrophobic functional group, and the surface of the low-k dielectric layer LK may be hydrophobic.

In an embodiment, the low-k dielectric layer LK may further include a photosensitive material. For example, the low-k dielectric layer LK may further include PAC or PAG.

The low-k dielectric layer LK may have a lower dielectric constant than the second organic insulating layer 118. In an embodiment, the dielectric constant of the low-k dielectric layer LK may be less than about 3. In an embodiment, the dielectric constant of the low-k dielectric layer LK may be less than about 2.8. In an embodiment, the dielectric constant of the low-k dielectric layer LK may be in a range of about 2.5 to about 2.7.

The second organic insulating layer 118 may include a material having a higher dielectric constant than the dielectric constant of the low-k dielectric layer LK. The second organic insulating layer 118 may include an organic material. For example, the second organic insulating layer 118 may include PSPI.

In an embodiment, the dielectric constant of the second organic insulating layer 118 may be greater than about 3. In an embodiment, the dielectric constant of the second organic insulating layer 118 may be greater than about 3.2. In an embodiment, the dielectric constant of the second organic insulating layer 118 may be in a range of about 3.5 to about 5.

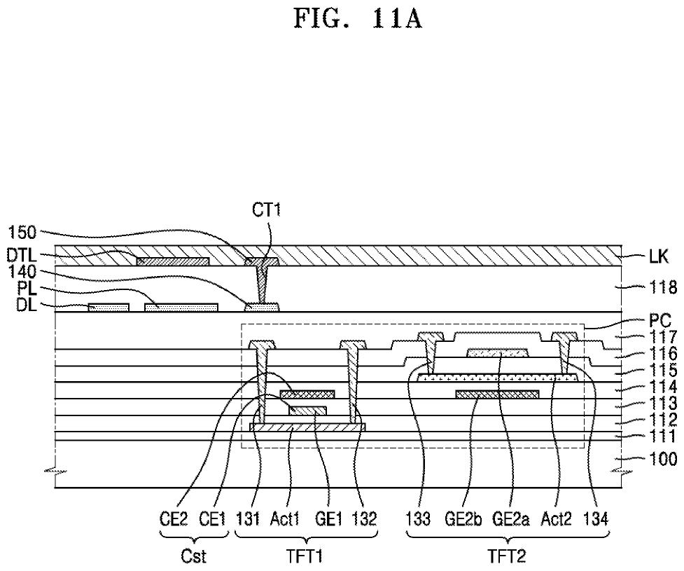

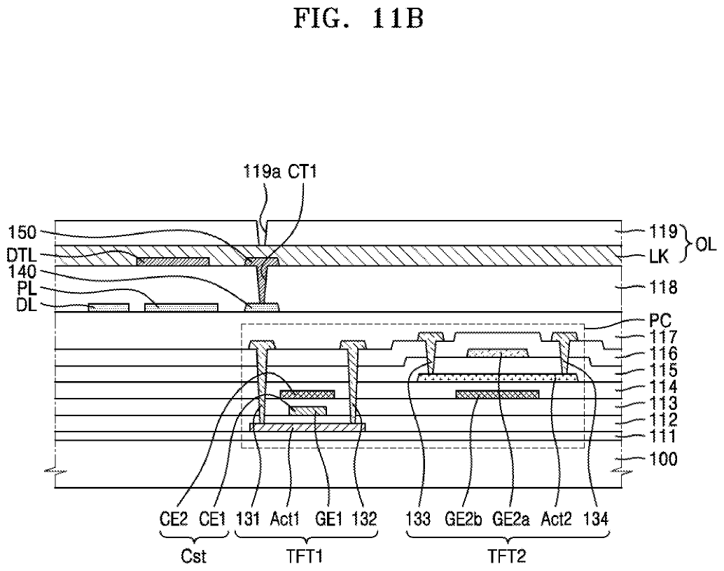

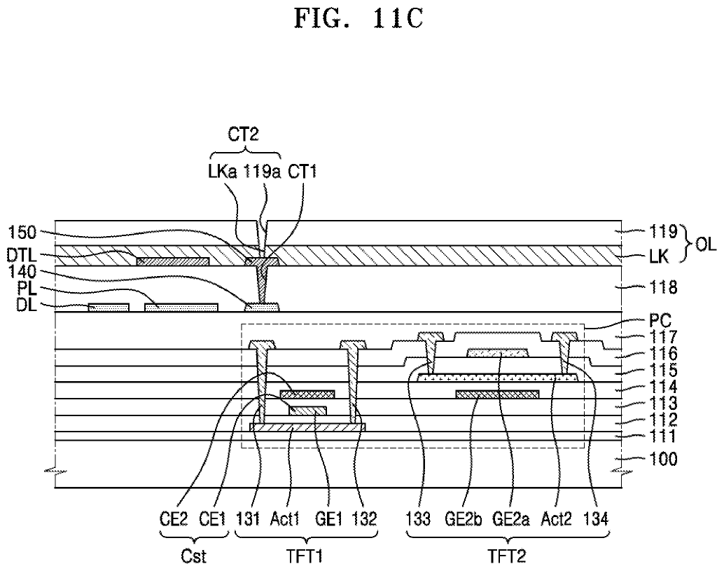

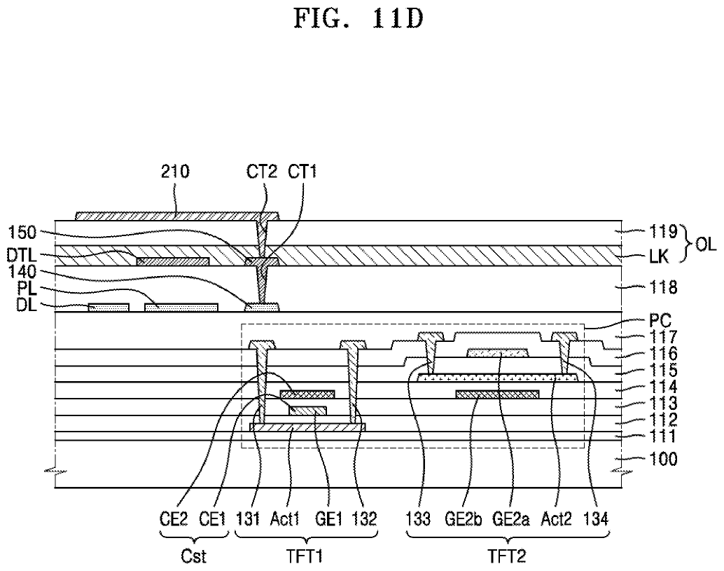

FIGS. 11A to 11D are schematic cross-sectional views illustrating a method of manufacturing the display apparatus of FIG. 5. The insulating layer OL illustrated in FIG. 5 may be formed by the following process.

Referring to FIG. 11A, the connection wire DTL and the second connection electrode 150 may be formed on the second organic insulating layer 118. The low-k dielectric layer LK may be formed to cover the connection wire DTL and the second connection electrode 150.

In an embodiment, the low-k dielectric layer LK may not include a photosensitive material. In an embodiment, the low-k dielectric layer LK may be manufactured by coating and hardening a material for forming a low-k dielectric layer. In an embodiment, the hardening process may be a thermal treatment process.

Referring to FIG. 11B, the third organic insulating layer 119 may be formed on the low-k dielectric layer LK. In an embodiment, the third organic insulating layer 119 may include a photosensitive material. For example, the third organic insulating layer 119 may include PSPI.

A photolithography process using a mask including a pattern corresponding to a hole 119 of the third organic insulating layer 119 may be used for forming the third organic insulating layer 119. A preliminary third organic insulating layer may be coated, exposed using a mask, and developed, thereby forming the third organic insulating layer 119. In an embodiment, the hole 119a of the third organic insulating layer 119 overlapping the second connection electrode 150 in a plan view may be formed.

Referring to FIG. 11C, a portion of the low-k dielectric layer LK may be etched using the third organic insulating layer 119 as an etch mask. A portion of the low-k dielectric layer LK may be removed. The etching process may be, for example, dry etch. A hole LKa of the low-k dielectric layer LK corresponding to the hole 119a of the third organic insulating layer 119 may be formed. The contact hole CT2 that penetrates the insulating layer OL may be formed.

In the process of removing a portion of the low-k dielectric layer LK using the third organic insulating layer 119 as an etch mask, the roughness of the upper surface of the third organic insulating layer 119 may be increased. In contrast, as the low-k dielectric layer LK is arranged below the third organic insulating layer 119 and protected, the roughness of the upper surface of the low-k dielectric layer LK may be less than the roughness of the upper surface of the third organic insulating layer 119. In an embodiment, the roughness of the upper surface of the low-k dielectric layer LK may be less than about 1 nm. In an embodiment, the roughness of the upper surface of the third organic insulating layer 119 may be greater than about 2 nm.

Referring to FIG. 11D, the sub-pixel electrode 210 may be formed on the insulating layer OL. The sub-pixel electrode 210 may overlap the contact hole CT2 in a plan view. The sub-pixel electrode 210 may be electrically connected to the second connection electrode 150 through the contact hole CT2 of the insulating layer OL. The sub-pixel electrode 210 may be electrically connected to the sub-pixel circuit PC through the second connection electrode 150 and the first connection electrode 140. A photolithography process may be used for forming the sub-pixel electrode 210. A photoresist layer may be formed on a preliminary sub-pixel electrode (not shown), exposed through a mask, and developed, thereby forming a photoresist pattern, and the preliminary sub-pixel electrode may be etched using the photoresist pattern as an etch mask. The sub-pixel electrode 210 may be formed after removing the photoresist pattern.

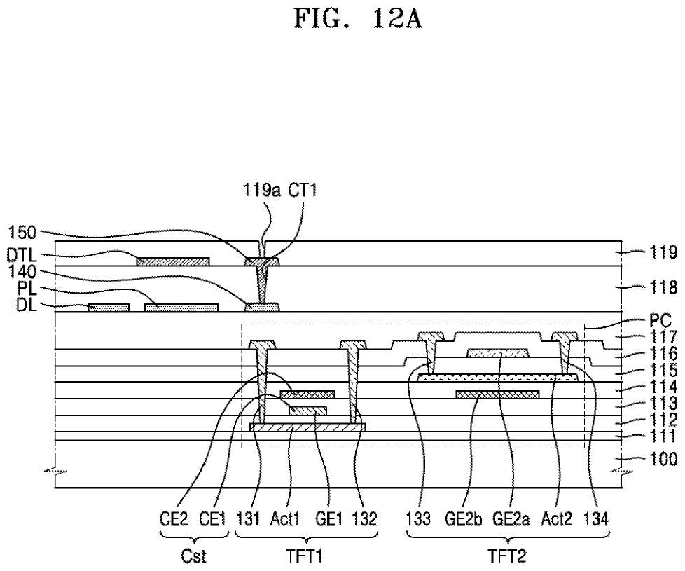

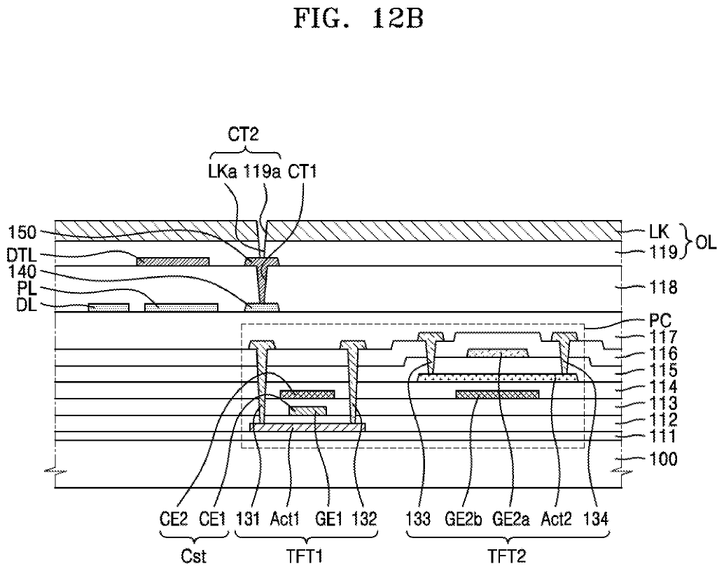

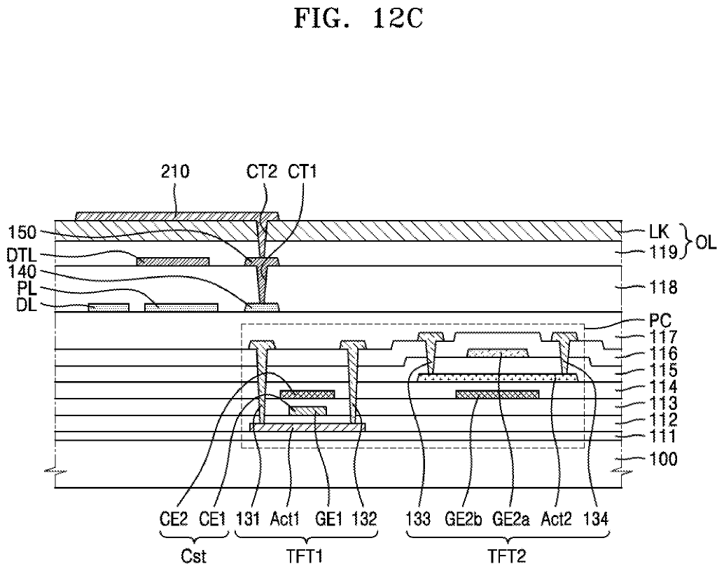

FIGS. 12A to 12C are schematic cross-sectional views illustrating a method of manufacturing the display apparatus of FIG. 6. The insulating layer OL illustrated in FIG. 6 may be formed by the following process.

Referring to FIG. 12A, the connection wire DTL and the second connection electrode 150 may be formed on the second organic insulating layer 118. The third organic insulating layer 119 may be formed to cover the connection wire DTL and the second connection electrode 150.

In an embodiment, the third organic insulating layer 119 may include a photosensitive material. For example, the third organic insulating layer 119 may include PSPI.

The photolithography process using a mask including a pattern corresponding to the hole 119a of the third organic insulating layer 119 may be used for forming the third organic insulating layer 119. The preliminary third organic insulating layer may be coated, exposed using a mask, and developed, thereby forming the third organic insulating layer 119. In an embodiment, the hole 119a of the third organic insulating layer 119 overlapping the second connection electrode 150 in a plan view may be formed.

Referring to FIG. 12B, the low-k dielectric layer LK may be formed on the third organic insulating layer 119. In an embodiment, the low-k dielectric layer LK may include a photosensitive material. In an embodiment, the low-k dielectric layer LK may further include PAC or PAG.

A photolithography process using a mask including a pattern corresponding to the hole LKa of the low-k dielectric layer LK may be used for forming the low-k dielectric layer LK. A preliminary low-k dielectric layer may be coated, exposed using a mask, and developed, thereby forming the low-k dielectric layer LK. In an embodiment, the hole LKa of the low-k dielectric layer LK overlapping the hole 119a of the third organic insulating layer 119 in a plan view may be formed. The contact hole CT2 that penetrates the insulating layer OL may be formed.

Referring to FIG. 12C, the sub-pixel electrode 210 may be formed on the insulating layer OL. The sub-pixel electrode 210 may overlap the contact hole CT2 in a plan view. The sub-pixel electrode 210 may be electrically connected to the second connection electrode 150 through the contact hole CT2 of the insulating layer OL. The sub-pixel electrode 210 may be electrically connected to the sub-pixel circuit PC through the second connection electrode 150 and the first connection electrode 140. A photolithography process may be used for forming the sub-pixel electrode 210.

According to an embodiment, a display apparatus for displaying a high-quality image while reducing the area of a dead space may be implemented. The scope of the disclosure is not limited by the above effects.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a display area and a peripheral area located adjacent to the display area;
a sub-pixel circuit on a substrate;
a light-emitting diode electrically connected to the sub-pixel circuit and including a sub-pixel electrode;
a first data line located in the display area and extending in a first direction;
an input line located in the peripheral area and extending toward the display area from the peripheral area; and
a connection wire located in the display area and transmitting a data signal input through the input line to the first data line, wherein
the connection wire includes:
a first connection line extending in the first direction; and
a second connection line extending in a second direction intersecting the first direction,
the first connection line overlaps the sub-pixel electrode in a plan view with an insulating layer interposed between the sub-pixel electrode and the first connection line,
the insulating layer includes:
a first insulating layer; and
a second insulating layer disposed on the first insulating layer,
a dielectric constant of the first insulating layer and a dielectric constant of the second insulating layer are different from each other, and
one of the first insulating layer and the second insulating layer includes benzocyclobutene (BCB).

2. The display apparatus of claim 1, wherein
the dielectric constant of the first insulating layer is lower than the dielectric constant of the second insulating layer, and
the first insulating layer includes BCB.

3. The display apparatus of claim 1, wherein
the dielectric constant of the second insulating layer is lower than the dielectric constant of the first insulating layer, and
the second insulating layer includes BCB.

4. The display apparatus of claim 2, wherein a roughness of an upper surface of the second insulating layer is greater than a roughness of an upper surface of the first insulating layer.

5. The display apparatus of claim 3, wherein the second insulating layer further includes a photosensitive material.

6. The display apparatus of claim 1, wherein the first connection line and the second connection line are integrally formed.

7. The display apparatus of claim 6, further comprising:
a second data line spaced apart from the first data line, intersecting the second connection line, and extending in the first direction, wherein the second connection line passes above the second data line and is not connected with the second data line.

8. The display apparatus of claim 1, wherein
the first connection line and the second connection line are disposed on different layers, and
the first connection line and the first data line are disposed on a same layer.

9. The display apparatus of claim 8, further comprising:
a second data line spaced apart from the first data line, intersecting the second connection line, and extending in the first direction, wherein the second connection line passes under the second data line and is not connected with the second data line.

10. The display apparatus of claim 1, wherein
the connection wire further includes a third connection line located in the display area and extending in the first direction, and
the third connection line is connected to the first data line in the peripheral area located adjacent to the display area.

11. A display apparatus comprising:
a display area and a peripheral area located adjacent to the display area;
a sub-pixel circuit on a substrate;
a light-emitting diode electrically connected to the sub-pixel circuit and including a sub-pixel electrode;
a first data line and a second data line located in the display area, extending in a first direction, and spaced apart from each other;
an input line located in the peripheral area and extending toward the display area from the peripheral area; and
a connection wire having an end electrically connected to the input line and another end electrically connected to the first data line, and passing through a portion of the display area located adjacent to the peripheral area, wherein
the connection wire includes:
a first connection line extending in the first direction; and
a second connection line extending in a second direction intersecting the first direction and intersecting the second data line,
the first connection line overlaps the sub-pixel electrode in a plan view with an insulating layer interposed between the sub-pixel electrode and the first connection line,
the insulating layer includes:
a first insulating layer; and
a second insulating layer disposed on the first insulating layer,
a dielectric constant of the first insulating layer and a dielectric constant of the second insulating layer are different from each other, and
one of the first insulating layer and the second insulating layer includes benzocyclobutene (BCB).

12. The display apparatus of claim 11, wherein
the dielectric constant of the first insulating layer is lower than the dielectric constant of the second insulating layer, and
the first insulating layer includes BCB.

13. The display apparatus of claim 11, wherein
the dielectric constant of the second insulating layer is lower than the dielectric constant of the first insulating layer, and
the second insulating layer includes BCB.

14. The display apparatus of claim 12, wherein a roughness of an upper surface of the second insulating layer is greater than a roughness of an upper surface of the first insulating layer.

15. The display apparatus of claim 13, wherein the second insulating layer further includes a photosensitive material.

16. The display apparatus of claim 11, wherein the first connection line and the second connection line are integrally formed.

17. The display apparatus of claim 16, wherein the second connection line is insulated from the second data line and passes above the second data line.

18. The display apparatus of claim 11, wherein the first connection line and the first data line are disposed on a same layer.

19. The display apparatus of claim 18, wherein
the second connection line passes under the second data line, and
the second connection line and the first connection line are disposed on different layers.

20. The display apparatus of claim 11, wherein
the connection wire further includes a third connection line located in the display area and extending in the first direction, and
the third connection line is connected to the first data line in the peripheral area located adjacent to the display area.
